(19) United States
(12) Patent Application Publication
(10) Pub. No.: US 2007/0259111 A1
(43) Pub. Date: Nov. 8, 2007

(54) METHOD AND APPARATUS FOR PHOTO-EXCITATION OF CHEMICALS FOR ATOMIC LAYER DEPOSITION OF DIELECTRIC FILM

(76) Inventors: Kaushal K. Singh, Santa Clara, CA (US); Maitreyee Mahajani, Saratoga, CA (US); Steve G. Ghanayem, Los Altos, CA (US); Joseph Yudovsky, Campbell, CA (US); Brendan McDougall, Livermore, CA (US)

Correspondence Address: PATTERSON & SHERIDAN, LLP, 3040 POST OAK BOULEVARD, SUITE 1500, HOUSTON, TX, 77056, US

(21) Appl. No.: 11/464,121

(22) Filed: Aug. 11, 2006

Related U.S. Application Data
(63) Continuation-in-part of application No. 11/381,970, filed on May 5, 2006.

(51) Int. Cl. C23C 16/00

(52) U.S. Cl. 427/248.1

(57) ABSTRACT

The invention generally provides a method for depositing materials, and more particularly, embodiments of the invention relate to chemical vapor deposition processes and atomic layer deposition processes utilizing photoexcitation techniques to deposit barrier layers, seed layers, conductive materials, and dielectric materials. Embodiments of the invention generally provide methods of the assisted processes and apparatuses, in which the assisted processes may be conducted for providing uniformly deposited material.

### CROSS-REFERENCE TO RELATED APPLICATIONS

This application is a continuation-in-part of co-pending U.S. patent application Ser. No. 11/381,970 (APPM/010749), filed May 5, 2006, which is herein incorporated by reference.

### BACKGROUND OF THE INVENTION

1. Field of the Invention

Embodiments of the invention generally relate to a method for depositing materials, and more particularly, embodiments of the invention relate to chemical vapor deposition processes and atomic layer deposition processes utilizing photoexcitation techniques to deposit barrier layers, seed layers, conductive materials, and dielectric materials.

2. Description of the Related Art

A substrate fabrication process is often evaluated by two related and important factors, which are device yield and the cost of ownership (COO). The COO, while affected by a number of factors, is greatly affected by the number of substrates processed per time, i.e., the throughput of the fabrication process, and cost of processing materials. Batch processing has been found to be promising in the attempt to increase throughput. However, providing processing conditions uniformly over an increased number of substrates is a challenging task.

In addition, plasma assisted ALD or CVD processes, UV assisted (photo-assisted) ALD or CVD processes, and ALD or CVD processes having assistance directly by ions provided to a processing area have been shown to be beneficial to some deposition processes. For example, UV and plasma assisted processes have been demonstrated to provide good film quality for high-k dielectrics which are increasingly needed as device scale approaches sub 65 nm applications. Plasma assisted ALD or CVD have also been demonstrated to reduce thermal budget and process time requirements as compared to similar thermally assisted processes.

Providing uniform process conditions over an increased number of substrates is even more challenging if additional assisting treatments are added to the processes as described above for plasma assisted ALD or CVD processes, UV assisted (photo-assisted) ALD or CVD processes, and ALD or CVD processes having assistance directly by ions provided to a processing area.

Plasma assisted ALD processes have used remote plasma generation to attempt exposing substrates to uniform plasma conditions within a batch chamber. The plasma is introduced through a delivery system such as the gas delivery system of the batch tool. However, this process may suffer from the relaxation of the plasma prior to entering the process region.

Therefore, there is a need for a method for uniformly and effectively depositing materials during ALD or CVD processes in a batch tool with UV assistance.

### SUMMARY OF THE INVENTION

The invention generally provides a method for depositing materials, and more particularly, embodiments of the invention relate to chemical vapor deposition processes and atomic layer deposition processes utilizing photoexcitation techniques to deposit barrier layers, seed layers, conductive materials, and dielectric materials. Embodiments of the invention generally provide methods of the assisted processes and apparatuses, in which the assisted processes may be conducted for providing uniformly deposited material.

According to one embodiment, a method for forming a metal nitride on a substrate is provided. The method comprises positioning a substrate within a process chamber, exposing the substrate to a deposition gas comprising a metal containing precursor and a nitrogen containing precursor, exposing the deposition gas to an energy beam derived from a UV-source within the process chamber, and depositing a metal nitride on the substrate. In one embodiment, the substrate is exposed to the energy beam during a pretreatment process prior to depositing the metal nitride or the substrate is exposed to the energy beam during a post-treatment process after depositing the metal nitride.

According to another embodiment, a method for forming a metal oxide on a substrate is provided. The method comprises positioning a substrate within a process chamber, exposing the substrate to a deposition gas comprising a metal containing precursor and an oxygen containing precursor, exposing the deposition gas to an energy beam derived from a UV-source within the process chamber, and depositing a metal oxide on the substrate. In one embodiment, the substrate is exposed to the energy beam during a pretreatment process prior to depositing the metal oxide. In one embodiment, the substrate is exposed to the energy beam after during a post-treatment process after depositing the metal oxide.

According to another embodiment, a method for forming a metal layer on a substrate is provided. The method comprises positioning a substrate within a process chamber, exposing the substrate to a deposition gas comprising a metal containing precursor and a reducing gas, exposing the deposition gas to an energy beam derived from a UV-source within the process chamber, and depositing a metal layer on the substrate. In one embodiment, the substrate is exposed to the energy beam during a pretreatment process prior to depositing the metal oxide. In one embodiment, the substrate is exposed to the energy beam after during a post-treatment process after depositing the metal oxide.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a sectional side view of an exemplary batch processing chamber of the invention including an assembly for exciting species of the processing gases;

FIG. 2 illustrates a sectional top view of a further embodiment of a batch processing chamber of the invention including an assembly for exciting species of the processing gases;

FIG. 3 illustrates a sectional side view of an embodiment of a batch processing chamber of the invention including an assembly for exciting species of the processing gases within a process region;

FIG. 4 illustrates a sectional side view of another embodiment of a batch processing chamber of the invention including an assembly for exciting species of the processing gases within a process region;

FIG. 5 illustrates a sectional side view of an exemplary batch processing chamber of the invention including an assembly for exciting species of the processing gases within an injector assembly;

FIG. 6 illustrates a sectional side view of another embodiment of an exemplary batch processing chamber of the invention including an assembly for exciting species of the processing gases within an injector assembly;

FIG. 7 illustrates a sectional side view of an even further embodiment of an exemplary batch processing chamber of the invention including an assembly for exciting species of the processing gases within an injector assembly;

FIG. 8 illustrates a sectional side view of another embodiment of an exemplary batch processing chamber of the invention including an assembly for exciting species of the processing gases within an injector assembly;

FIG. 9 illustrates a sectional side view of another embodiment of an injector assembly for a batch processing chamber of the invention including an assembly for exciting species of the processing gases within an injector assembly;

FIG. 10 is a flow diagram for the process for depositing a barrier material as described by embodiments herein;

FIG. 11 is a flow diagram for the process for depositing a dielectric material as describe by embodiments herein;

FIG. 12 is a flow diagram for the process for depositing a conductive material as described by embodiments herein;

FIG. 13 is a flow diagram for the process for depositing a seed layer as described by embodiments herein; and

FIG. 14A-14D illustrate schematic cross-sectional views of an integrated circuit fabrication sequence.

### DETAILED DESCRIPTION

The invention generally provides an apparatus and a method for processing semiconductor substrates in a batch with assemblies for assisting the processes by generated ions. In one embodiment of the invention, a batch processing chamber with an excitation assembly, which is positioned within the batch processing chamber housing, is provided. An example of a batch processing chamber which may be useful for one embodiment described herein is a FLEXSTAR® system, available from Applied Materials, Inc., located in Santa Clara, Calif.

Generally, excited species of processing gases may be generated to assist the ALD or CVD processes as described herein. These species may be excited by plasma assistance, UV assistance (photo assistance), ion assistance (e.g., ions generated by an ion source), or combinations thereof. The species are excited in or in the vicinity of the process region within the chamber housing to avoid relaxation of the excited states before the ions reach the process region of the batch processing chamber.

A “substrate” as referred to herein, includes, but is not limited to, semiconductor wafers, semiconductor workpieces, and other workpieces such as optical planks, memory disks and the like. Embodiments of the invention may be applied to any generally flat workpiece on which material is deposited by the methods described herein.

“Vertical direction” and “horizontal direction” are to be understood as indicating relative directions. Thus, the horizontal direction is to be understood as substantially perpendicular to the vertical direction and vice versa. Nevertheless, it is within the scope of the invention that the described embodiments and aspects may be rotated in its entirety such that the dimension referred to as the vertical direction is oriented horizontally and, at the same time, the dimension referred to as the horizontal direction is oriented vertically.

A batch processing chamber for ALD or CVD processing useful for embodiments described herein is described in commonly assigned U.S. Ser. No. 11/249,555, entitled “Reaction Chamber with Opposing Pockets for Gas Injection and Exhaust,” filed Oct. 13, 2005, which is incorporated herein by reference for providing further description of a chamber, a heating system, a gas delivery system, and an exhaust system.

### Hardware

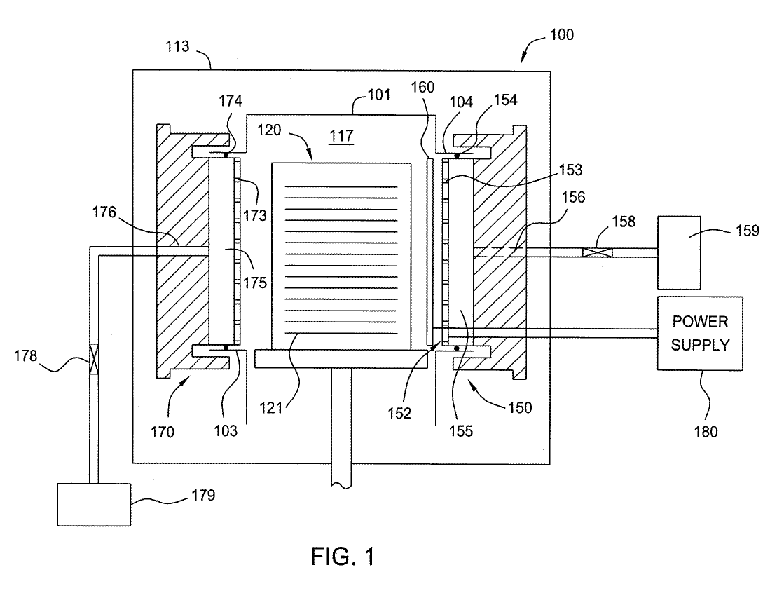

FIG. 1 illustrates one embodiment of a batch processing chamber having an inner chamber 101 (e.g., a quartz chamber), and controlled inject and exhaust. Typically, the inject assembly 150 and the exhaust assembly 170 are temperature controlled to avoid condensation of processing gases. FIG. 1 is a sectional side view of a batch processing chamber 100. The batch processing chamber 100 generally contains an inner chamber 101 defining a process region 117 configured to accommodate a batch of substrates 121 stacked in a substrate boat 120. The substrates are provided in the process region to be processed by various deposition processes, such as an ALD process or a CVD process. Generally, one or more heater blocks (not shown) are arranged around the inner chamber 101 and are configured to heat the substrates 121 provided in the process region 117. In one embodiment, the inner chamber 101 may for example be a quartz chamber. An outer chamber 113 is generally disposed around the inner chamber 101. One or more thermal insulators (not shown) may be provided between the outer chamber 113 and any heaters in order to keep the outer chamber cool.

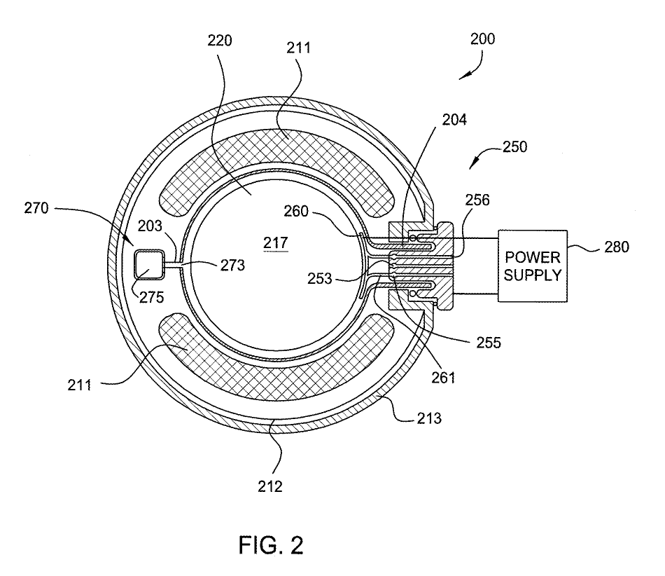

An example of the heater blocks and the thermal insulators, which may be used in the embodiment shown in FIG. 1, is shown in the embodiment of FIG. 2. FIG. 2, shows one or more heater blocks 211, which are arranged around the inner chamber 201 and are configured to heat the substrates provided in the process region. An outer chamber 213 is generally disposed around the inner chamber 201. In one embodiment, the inner chamber 201 may, for example, be a quartz chamber. In FIG. 2, thermal insulators 212 are be provided between the outer chamber 213 and any heaters in order to keep the outer chamber cool.

FIG. 1 shows the inner chamber 101, e.g., a quartz chamber, generally containing a chamber body having an opening on the bottom, an injector pocket formed on one side of the chamber body, an exhaust pocket formed on the chamber body on an opposite side of the injector pocket. The inner chamber 101 has a cylindrical shape similar to that of the substrate boat 120. Thereby, the process region 117 may be kept small. A reduced process region reduces the amount of processing gas per batch and shortens residence time during batch processing.

In one embodiment, the exhaust pocket 103 and the injector pocket 104 may be welded in place with slots milled on the chamber body of inner chamber 101. According to one embodiment, the injector pocket and the exhaust pocket are flattened quartz tubing with one end welded on the chamber body and one end open. The injector pocket 104 and the exhaust pocket 103 are configured to house injector assembly 150 and exhaust assembly 170. As described in more detail in U.S. Ser. No. 11/249,555, entitled “Reaction Chamber with Opposing Pockets for Gas Injection and Exhaust,” filed Oct. 13, 2005, incorporated by reference above, injector assembly 150 and exhaust assembly 170 may typically be temperature controlled. Further, a support plate for supporting the inner (quartz) chamber is further connected to a load lock positioned below the bottom opening of inner chamber 101. The substrate boat 120 may be loaded and unloaded through the load lock. The substrate boat 120 may be vertically translated between the process region 117 and the load lock via the opening at the bottom of the inner chamber.

Examples of substrate boats that may be used in batch processing chambers and during processes described herein are further described in U.S. Ser. No. 11/216,969, entitled “Batch Deposition Tool and Compressed Boat,” filed Aug. 31, 2005, which is incorporated herein by reference. Examples of methods and apparatuses for loading and unloading substrate boats used in batch processing is further described in U.S. Ser. No. 11/242,301, entitled “Batch Wafer Handling System,” filed Sep. 30, 2005, which is incorporated herein by reference.

The heater blocks are generally wrapped around an outer periphery of the inner chamber 101 except near the injector pocket 104 and the exhaust pocket 103. According to another embodiment (not shown) the heater blocks 211 may also be wrapped around the injector pocket 104 and/or the exhaust pocket 103. The substrates 121 are heated to an appropriate temperature by the heater blocks through the inner chamber 101. The heaters are controlled to achieve uniform heating of the substrates. In one embodiment, points on the substrates 121 in a batch process attain the same set point temperature plus or minus 1 degree Celsius. Configurations of the batch processing chamber 100 improve temperature uniformity in batch processing. For example, a cylindrical shape of the inner chamber 101 results in edges of the substrates 121 evenly distanced from the inner chamber. Also, the heaters may have multiple controllable zones to adjust variations of temperature between regions. The heater blocks may be made of resistive heaters arranged in multiple vertical zones. In one example, the heater blocks may be ceramic resistive heaters.

FIG. 1 illustrates that the injector pocket 104 may be welded on a side of the chamber body defining an inject volume in communication with the process region 117. The inject volume typically extends along the entire height of the substrate boat 120 when the substrate boat is in a process position. The injector assembly 150 disposed in the injector pocket may, thus, provide a horizontal flow of processing gases to every substrate 121.

A recess is formed to hold walls of the injector pocket 104. The injector assembly is thermally isolated, e.g., by seal 154. Seal 154, which may be an o-ring or other suitable elements, also provide a vacuum seal to control the pressure in the inner chamber 101. Thermal isolation of the injector assembly may be desired to independently control the temperature of the injector.

Since the process region 117 and the injector volume are usually kept in a vacuum state during process, an outer volume between inner chamber 101 and chamber 113 may also be evacuated. Keeping the outer volume under a reduced pressure may reduce pressure generated stress on inner chamber 101. Additional vacuum seals, such as o-rings, may be disposed between appropriate parts of chamber 100, in order to control the pressure of the process region 117, the vacuum/pressure stress applied to inner chamber 101, to control gas flow of inserted processing gases only towards the process region. Further, one or more vacuum pumps may be directly or via additional exhaust plenums (not shown) connected to the inner chamber in order to control the pressure in the inner chamber 101.

The temperature of various components in a batch processing chamber may be independently controllable, especially when a deposition process is to be performed in the batch processing chamber. If the temperature of the injector assembly is too low, the gas injected may condense and remain on the surface of the injector assembly, which can generate particles and affect the chamber process. If the temperature of the injector assembly is high enough to evoke gas phase decomposition and/or surface decomposition which may “clog” paths in the injector assembly. An injector assembly of a batch processing chamber is heated to a temperature lower than a decomposition temperature of a gas being injected and higher than a condensation temperature of the gas. The temperature of the injector assembly is generally different than the processing temperature in the process region. In one example, substrates may be heated up to about 600 degrees Celsius, while the temperature of the injector assembly is about 80 degrees Celsius during an atomic layer deposition process. Therefore, the temperature of the injector assembly is controlled independently.

FIG. 1 illustrates that the exhaust pocket 103 may be welded on a side of the chamber body defining an exhaust volume in communication with the process region 117. The exhaust volume typically covers an entire height of the substrate boat 120 when the substrate boat is in a process position such that the exhaust assembly disposed in the exhaust pocket may provide a horizontal flow of processing gases to every substrate 121.

A recess is formed to hold walls of the exhaust pocket 103. The exhaust assembly is thermally isolated, e.g., by seal 174. Seal 174, which may be an o-ring or other suitable elements, also provide a vacuum seal to be able to control the pressure in the inner chamber 101. Thermal isolation of the exhaust assembly may be desired to independently control the temperature of the exhaust.

Since the process region 117 and the exhaust volume are usually kept in a vacuum state during process, an outer volume between inner chamber 101 and chamber 113 may also be evacuated. Keeping the outer volume vacuumed can reduce pressure generated stress on the inner chamber 101. Additional vacuum seals, such as o-rings, may be disposed between appropriate parts of chamber 100, in order to control the pressure of the process region 117, the vacuum/pressure stress applied to inner chamber 101, to control gas flow of inserted processing gases only towards the process region. Further, one or more vacuum pumps may be directly or via additional exhaust plenums (not shown) connected to the inner chamber in order to control the pressure in the inner chamber 101.

Temperature of various components in a batch processing chamber may be controlled independently, especially when a deposition process is to be performed in the batch processing chamber. On the one hand, it is desirable to keep the temperature in the exhaust assembly lower than the temperature in the processing chamber such that the deposition reactions do not occur in the exhaust assembly. On the other hand, it is desirable to heat an exhaust assembly such that processing gases passing the exhaust assembly do not condense and remain on the surface causing particle contamination. If deposition of reaction byproducts on the exhaust assembly does occur, then elevated temperatures on the exhaust assembly may ensure that the deposition has good adhesion. Therefore, the exhaust assembly may be heated independently from the process region.

FIG. 1 illustrates that additionally a gas source 159 is provided. The gas source 159 provides processing gas, like precursor gases or deposition gases, treatment gases, carrier gases, and purge gases via valve 158 and via inlet channel 156 into the vertical channel 155 of the injector assembly. The vertical channel 155 may also be denoted as plenum 155 or cavity 155. The processing gas enters the process region 117 through openings 153 of the injector assembly. The plate and openings form a faceplate 152 to have a uniform distribution of the gas over the substrates 121 in the substrate boat 120.

Generally, carrier gases and purge gases, which may be used as a processing gas, include N₂, H₂, Ar, He, combinations thereof, and the like. During pretreatment steps H₂, NH₃, B₂H₆, Si₂H₄, SiH₆, H₂O, HF, HCl, O₂, O₃, H₂O₂ or other known gases may be used as a processing gas. In one embodiment, deposition gases or precursor gases may contain a hafnium precursor, a silicon precursor or a combination thereof.

Exemplary hafnium precursors include hafnium compounds containing ligands such as halides, alkylaminos, cyclopentadienyls, alkyls, alkoxides, derivatives thereof or combinations thereof. Hafnium precursors useful for depositing hafnium-containing materials include HfCl₄, (Et₂N)₄Hf, (Me₂N)₄Hf, (MeEtN)₄Hf, (^{t}BuC₅H₄)₂HfCl₂, (C₅H₅)₂HfCl₂, (EtC₅H₄)₂HfCl₂, (Me₅C₅)₂HfCl₂, (Me₅C₅)HfCl₃, (ⁱPrC₅H₄)₂HfCl₂, (ⁱPrC₅H₄)HfCl₃, (^{t}BuC₅H₄)₂HfMe₂, (acac)₄Hf, (hfac)₄Hf, (tfac)₄Hf, (thd)₄Hf, (NO₃)₄Hf, (^{t}BuO)₄Hf, (ⁱPrO)₄Hf, (EtO)₄Hf, (MeO)₄Hf, or derivatives thereof. Exemplary silicon precursors include SiH₄, Si₂H₆, TDMAS, Tris-DMAS, TEOA, DCS, Si₂Cl₆, BTBAS or derivatives thereof.

Alternative metal precursors used during vapor deposition processes described herein include ZrCl₄, Cp₂Zr, (Me₂N)₄Zr, (Et₂N)₄Zr, TaF₅, TaCl₅, (^{t}BuO)₅Ta, (Me₂N)₅Ta, (Et₂N)₅Ta, (Me₂N)₃Ta(N^{t}Bu), (Et₂N)₃Ta(N^{t}Bu), TiCl₄, TiI₄, (ⁱPrO)₄Ti, (Me₂N)₄Ti, (Et₂N)₄Ti, AlCl₃, Me₃Al, Me₂AlH, (AMD)₃La, ((Me₃Si)(^{t}Bu)N)₃La, ((Me₃Si)₂N)₃La, (^{t}Bu₂N)₃La, (ⁱPr₂N)₃La, derivatives thereof or combinations thereof.

Even though FIG. 1 shows only one gas source, a person skilled in the art will appreciate that a plurality of gas sources, for example, one gas source for a first precursor, one gas source for a second precursor, and one gas source for a carrier and purge gas, may be coupled to the batch processing chamber 100. A gas flow from the different gases may be switched on or off according to the desired needs for a process. Thereby, 3- or 4-way valves may be used to provide the different gases to the inlet channel 156. Alternatively, two, three, or more inlet channels 156 may milled horizontally across the inject assembly 150 and several vertical channels 155 may be provided to insert different processing gases in the process region.

As an example, injector assembly 250 has more than one inlet channel, e.g., three inlet channels 256, as illustrated in FIG. 2. In one embodiment, each of the three inlet channels 256 is configured to supply the process region 117 with a processing gas independently from each other. Each inlet channel 256 is connected to a vertical channel 255. The vertical channels 255 may also be denoted as cavities 255 or plenums 255. The vertical channels 255 are further connected to a plurality of evenly distributed horizontal holes 253 and form a vertical faceplate on the center portion of the injector assembly 250.

On the opposite end of inner chamber 101 from injector assembly 150 an exhaust pocket 103 is provided in chamber 101. Exhaust pocket receives exhaust assembly 170. An exhaust port 176 is formed horizontally across the exhaust assembly 170 near a center portion. The exhaust port 176 opens to a vertical compartment 175 formed in the center portion. The vertical compartment 175 is further connected to a plurality of horizontal slots 173 which are open to the process region 117. When the process region 117 is being pumped out with vacuum pump 179 via valve 178, processing gases first flow from the process region 117 to the vertical compartment 175 through the plurality of horizontal slots 173. The processing gases then flows into an exhaust system via the exhaust port 176. In one aspect, the horizontal slots 173 may vary in size depending on the distance between a specific horizontal slot 173 and the exhaust port 176 to provide an even draw across the substrate boat 120 from top to bottom.

Processing gases such as precursor gases, deposition gases, treatment gases, purge or carrier gases, as described in more detail above, are delivered to and from process region 117 by injector assembly and exhaust assembly. A uniform gas flow across each substrate 121 as well as a uniform gas flow across all substrates vertically aligned in the substrate boat 120 is desired. However, non-uniformity might be caused by irregularities in the gas flow at the wafer edges. These irregularities may be prevented by providing a diffuser 160 between the injector and the substrate boat. The diffuser 160 may prevent the gas flow from direct impact on the edge of the substrate. Diffuser 160 may have a V-shaped form and may direct gas from the inlet tangentially along the substrates.

The diffuser may be provided in various shapes and positions. Generally, the diffuser may be provided between the faceplate of the injector assembly and the substrate boat. Thereby, the diffuser may be integrated in the substrate assembly and/or may be positioned in the injector pocket of the inner chamber 101. Various embodiments of diffusers which may be used in chambers and methods of the application are described in more detail in U.S. patent application, entitled: “Batch Processing Chamber with Diffuser Plate and Injector Assembly”, filed on an even dated herewith (U.S. patent application Ser. No. 11/381,966), which is incorporated herein by reference.

The gas flow with improved uniformity carries ionized species of the processing gases, like precursor gases or carrier or purge gases. The uniformity of the gas flow also improves the uniformity of the ionized species, which are used to provide plasma assisted, UV assisted, or ion assisted processes. Generally, the process assistance by plasma, UV, ion generation can be characterized as exciting the introduced gas or by ionizing the introduced gases. The components providing the processing gas flow to the process region 117 are configured to form a uniformly deposited material across each substrate and across the substrates in the substrate boat.

Plasma assisted batch processing has previously been conducted with a remote plasma source. However, a remote plasma is generated at larger distances with regard the process region. Thus, the number of excited species within the plasma has already considerably decreased as the plasma enters the process region. A remote plasma source results in a relaxation of the plasma before the plasma enters the process region.

The invention generally provides an apparatus and a method for processing semiconductor substrates in a batch tool, in which, e.g., the plasma for plasma assisted processing of substrates is provided in the process region or close or adjacent to the process region. Close or adjacent to the process region is to be understood as having the plasma generation directly neighboring the process region, or at least within the inner chamber, the injector pocket, or the injector assembly.

An embodiment illustrated in FIG. 1 includes a power source 180 to generate a plasma, which is connected to the diffuser 160 and the faceplate 152 of the injector assembly 150. A plasma is generated between the diffuser 160 and the faceplate 152 of the injector assembly 150. The injector face is used as an anode and the diffuser is used as a cathode to generate a plasma therebetween. The power applied to generate the plasma can be adapted to the desired application and may depend on the energy necessary to ionize particular species in the processing gas flowing into the process region. As a result, the plasma power may vary depending on the process step presently conducted. For example, for a plasma assisted ALD process, a different power maybe applied during a gas flow of a first precursor, during purging or pumping to remove the first precursor, during gas flow of a second precursor and during purging or pumping to remove the second precursor. Alternatively, some of the process steps may be conducted at similar plasma power or without plasma assistance. For example the purge steps may be conducted with the same power or without power, whereas for the times when precursors are provided to the process region, plasma power adapted for the first and second precursor, respectively, is applied.

As already mentioned above, barrier seal 154 is disposed between the injector pocket 104 and the injector assembly 150, and barrier seal 174 is disposed between the exhaust pocket 103 and the exhaust assembly 170. Thereby, processing chemicals are prevented from entering any undesirable areas in the batch processing chamber. Further, a vacuum seal for the quartz chamber may be provided by seals 154, 174. Additionally, the seals, which may be provided in the form of O-rings or the like, can electrically insulate different components within the chamber from each other. This is of increasing relevance as the power provided by power supply 180 increases. Higher voltages applied to electrodes, e.g., the injector assembly, may require improved electrical insulation of the injector assembly.

Within an embodiment shown in FIG. 1, the plasma may be confined between the face of the injector assembly 150 and the diffuser 160. Thereby, direct exposure of the substrate to a plasma may be avoided. This might be desirable to prevent plasma damage to the surfaces of the substrates. Accordingly, the diffuser shields the substrates from the plasma.

In the embodiments described while making reference to FIG. 1, a plasma is generated in the horizontal direction. The plasma extends along the vertical direction of the diffuser 160 and the injector assembly 150. Thus, the horizontal plasma extends along the vertical direction of the process region 117. The substrates 121 in the substrate boat 120 are exposed to the plasma along the entire stack of substrates. The previously described uniform gas flow provides a uniform distribution of ionized species of the plasma across the wafers.

FIG. 2 illustrates a further embodiment of a batch processing chamber having an inner chamber 201, and controlled inject and exhaust. Typically, the injector assembly 250 and the exhaust assembly 270 are temperature controlled to avoid condensation of processing gases. FIG. 2 is a sectional top view of a batch processing chamber 200. The batch processing chamber 200 generally contains an inner chamber 201 defining a process region 217 configured to accommodate a batch of substrates stacked in a substrate boat 220. The substrates are provided in the process region to be processed by various deposition processes, such as an ALD process or a CVD process. Generally, one or more heater blocks 211, which are arranged around the inner chamber 201 and are configured to heat the substrates provided in the process region. An outer chamber 213 is generally disposed around the inner chamber 201. In FIG. 2, thermal insulators 212 are provided between the outer chamber 213 and any heaters in order to keep the outer chamber cool.

The inner chamber 201, e.g., a quartz chamber, generally comprises a chamber body having an opening on the bottom, an injector pocket formed on one side of the chamber body, an exhaust pocket formed on the chamber body on an opposite side of the injector pocket. The inner chamber 201 has a cylindrical shape similar to that of the substrate boat 220. Thereby, the process region 117 is kept relatively small. A reduced process region reduces the amount of processing gas per batch and shortens residence time during batch processing.

The exhaust pocket 203 and the injector pocket 204 may be welded in place with slots milled on the chamber body. According to an alternative embodiment, the exhaust pocket may be provided in the form of vertically aligned tubes connecting the processing region with the vertical compartment 275. According to one embodiment, the injector pocket 204 and the exhaust pocket 203 are flattened quartz tubing with one end welded on the chamber body and one end open. The injector pocket 204 and the exhaust pocket 203 are configured to house injector assembly 250 and exhaust assembly 270. Injector assembly 250 and exhaust assembly 270 are typically temperature controlled.

An embodiment illustrated in FIG. 2 includes a power source 280 to generate a plasma, which is connected to the diffuser 260 and the faceplate 252 of the injector assembly 250. A plasma is generated between diffuser 260 and the face of the injector assembly. The injector face is used as an anode and the diffuser is used as a cathode to generate a plasma therebetween. The power applied to generate the plasma can be adapted to the desired application and may depend on the energy necessary to ionize particular species in the processing gas flowing into the process region. As a result, the plasma power may vary depending on the process step presently conducted. For example, for a plasma assisted ALD process, a different power maybe applied during a gas flow of a first precursor, during purging or pumping to remove the first precursor, during gas flow of a second precursor and during purging or pumping to remove the second precursor.

Alternatively, some of the process steps may be conducted at similar plasma power or without plasma assistance. For example, the purge steps may be conducted with the same power or without power, whereas plasma power adapted for the first and second precursor, respectively, is applied during the injection of the respective precursor gases.

In one embodiment, as shown in FIG. 2, the plasma may be confined between the face of the injector assembly 250 and the diffuser 260. Thereby, direct exposure of the substrate to a plasma may be avoided. This might be desirable to prevent plasma damage to the surfaces of the substrates. Accordingly, the diffuser shields the substrates from the plasma.

In the embodiments described while making reference to FIG. 2, a plasma in horizontal direction is generated. The plasma extends along the vertical direction of the diffuser and the injector assembly. Thus, the horizontal plasma extends along the vertical direction of the process region 217. The substrates in the substrate boat 220 are exposed to the plasma along the entire stack of substrates. The previously described uniform gas flow provides a uniform distribution of ionized species of the plasma across the wafers.

The batch processing chamber 200 includes an outer chamber 213, heater blocks 211 separated from the outer chamber by thermals insulators 212. An inner chamber 201 including injector pocket 204 and exhaust pocket 203 or exhaust tubes surrounds substrate boat 220 located in the process region. The injector assembly 250 has three inlet channels 256. Processing gas can be provided through the channels to vertical channels 255 and enters the processing location through openings 253 in the face of injector assembly 250. The exhaust assembly 270 includes exhaust port 176, vertical compartment 275 and horizontal slots 273.

Further, a v-shaped diffuser 260 is shown. Similarly to FIG. 1, a power source is coupled via the injector assembly to the injector face and the diffuser to generate a plasma between the injector face and the diffuser. FIG. 2 further illustrates a conductive mesh 261 that further confines the plasma in the gap between the diffuser and the injector face. The diffuser may additionally be made permeable to confine the plasma and to improve protection of the substrates from energetic particles. A permeable diffuser may improve the uniformity of the gas flow across the wafer. In the case of a permeable diffuser, the diffuser may be provided in the form of a mesh. According to another embodiment (not shown), mesh 261 and a permeable mesh diffuser 260 may be provided as one unit to provide a cathode and to confine the plasma between this cathode and the face of the injector assembly acting as the anode. The confinement of plasma—if desired—may be improved by minimizing or omitting a gap between the injector assembly and the mesh or diffuser. Nevertheless, it is to be understood that insulation may be provided in the event neighboring elements form the anode and the cathode for plasma ignition and maintenance.

The conductive and permeable mesh, the diffuser and the face of the injector assembly extend along the direction in which the substrates are stacked over each other in the substrate boat. In the embodiments shown herein, this direction is the vertical direction. The substrates are vertically stacked. As the plasma is generated adjacent to the process region along the entire height of the process region, on the one hand it is possible to provide uniform plasma assisted process conditions in the process region. On the other hand, since the plasma is generated adjacent the process region hardly any relaxation of the excitation occurs until the excited species get in contact with the substrates in the process region.

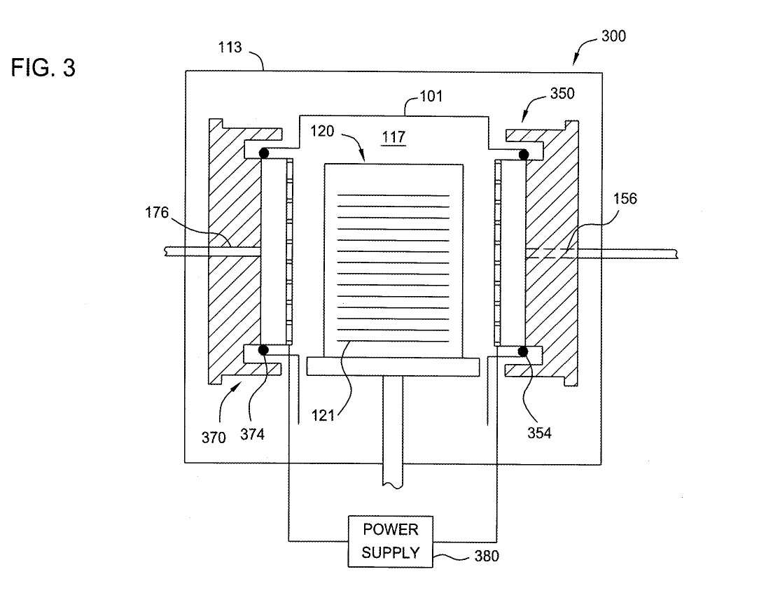

FIG. 3 illustrates another embodiment of a batch processing chamber 300 wherein plasma assisted ALD processes, plasma assisted CVD processes or other plasma assisted processes may be conducted. Within FIG. 3, elements that are the same in the embodiment of FIG. 1 are denoted with the same reference numbers. Alternatively, these elements may be the same as in the embodiment shown in FIG. 2. A repetition of the description of these elements and the related purposes or usage is omitted for simplicity.

A power supply 380 is connected to the injector assembly 350 and the exhaust assembly 370 in order to generate a plasma between the face of the injector and the opposing port of the exhaust.

The plasma is generated horizontally, that is parallel to the surfaces of the substrates. The plasma extends along the process region 117 of the inner chamber 101. The exhaust port may be used as the cathode and the face of the injector assembly may be used as the anode. In light of the increased distance between the anode and the cathode, the voltage provided by the power supply between the cathode and the anode has to be increased in order to provide the same electrical field acting on the species of the processing gas. As a result of the increased potential difference, the charged components may need further electrical isolation from surrounding components. In FIG. 3, this is indicated by an increased gap between the injector assembly 350 and the injector pocket of the inner chamber 101. Further, the gap of the exhaust assembly 370 is increased. Seals 354 and 374 are also increased in size to indicate the further electrical insulation. Even though, in the case of a quartz chamber, an insulation of the face of the injector assembly and the port of the exhaust assembly may partly be provided by the non-conductive inner chamber, potentials sufficiently high to create a plasma across the process region may need additional insulation of components in the batch processing chamber 300.

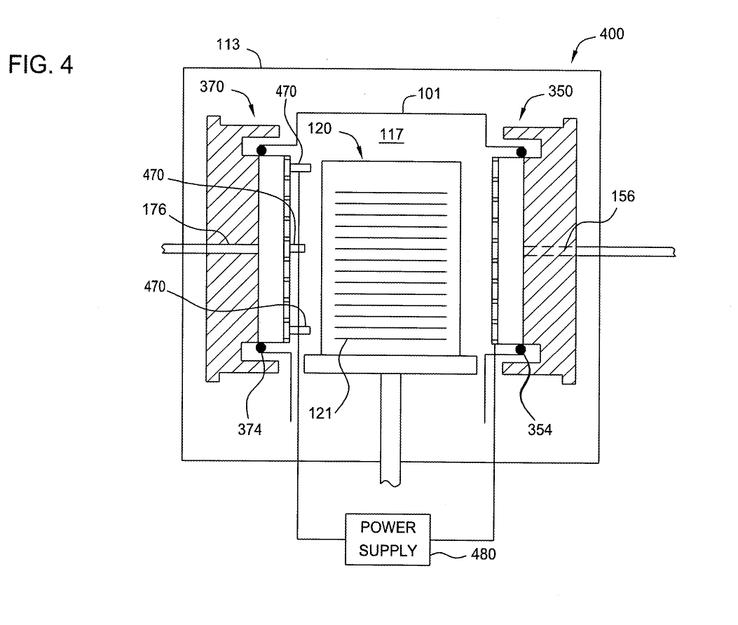

A further embodiment of a batch processing chamber 400 providing the option of conducting plasma assisted processes is shown in FIG. 4. Within FIG. 4, elements that are the same in the embodiments of FIG. 1 or other previous embodiments are denoted with the same reference numbers. Alternatively, these elements may be the same as in the embodiment shown in FIG. 2. A repetition of the description of these elements and the related purposes or usage is omitted for simplicity.

Within FIG. 4, as compared to chamber 300 of FIG. 3, an electrode 470 is positioned in the inner chamber 101. The electrode 470 or the electrodes 470 may be provided in the form of a rod disposed within the chamber cavity adjacent to the exhaust assembly. Power supply 480 is connected to electrodes 470 and to the injector assembly 350. The faceplate of the injector assembly acts as an electrode. Within the embodiment shown in FIG. 4, a plasma is generated horizontally, parallel to the substrate surfaces of the substrates in the substrate boat. The generated plasma extends across the process region and is exposed to the substrates.

FIG. 4 shows three rods 470 as electrodes for plasma generation. Alternatively, one or two vertical rods may also be used as electrodes. Further, 4 or more rods may be used as electrodes. The number and the arrangement of electrodes should be adapted to provide a uniform plasma across the substrates and to not disturb the uniformity of the gas flow of the processing gases.

According to another embodiment (not shown), the rods may also be positioned between the face of the injector assembly and the substrate boat. Thereby, a plasma generation comparable to FIG. 1 may occur. The plasma is generated adjacent the substrate boat within inner chamber 101, e.g., a quartz chamber. The plasma is generated horizontally between the vertically extending face of the injector assembly and the vertically extending set of rods. Thereby, a direct exposure of the substrates to the plasma may be reduced. However, the species of the processing gas, which have been excited by the plasma, have little time to relax before getting in contact with the substrate surface. As a further alternative (not shown), electrodes may also be disposed at other locations in the inner chamber 101.

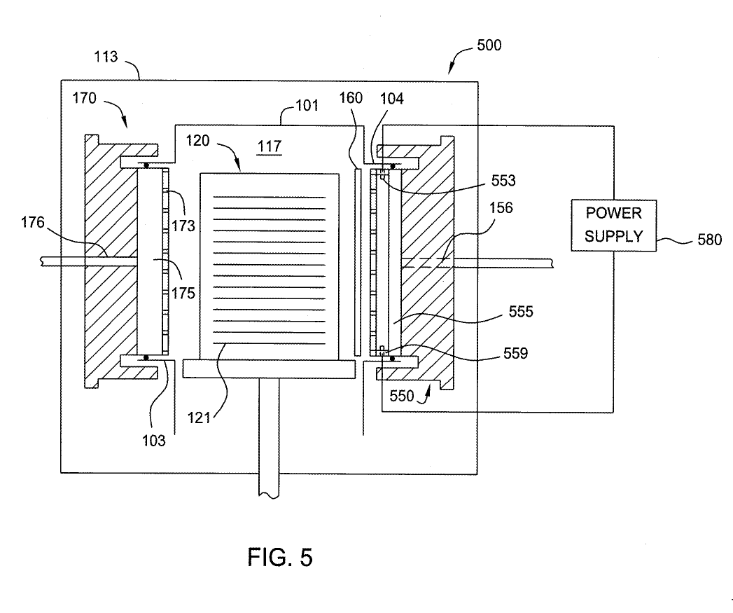

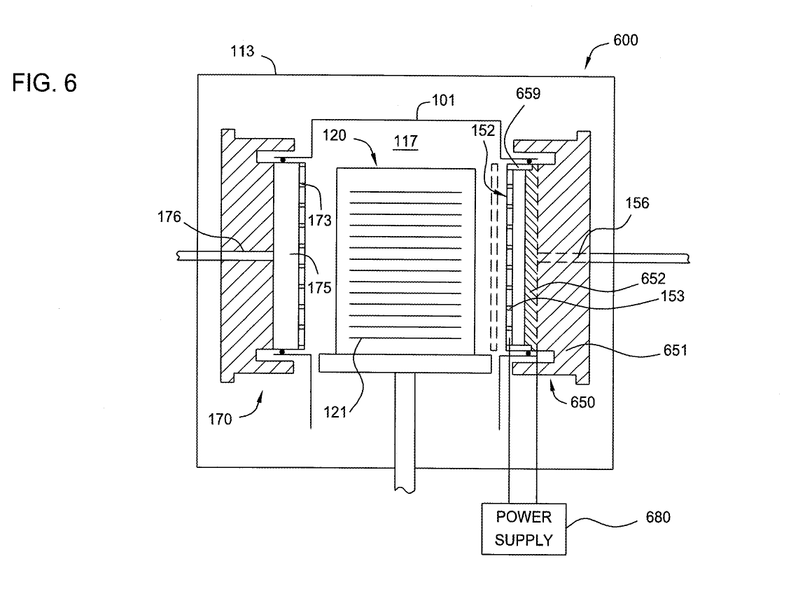

FIGS. 5 and 6 illustrate further embodiments. Elements that are the same in the embodiments of FIG. 1 or other previous embodiments are denoted with the same reference numbers. Alternatively, these elements may be the same as in the embodiment shown in FIG. 2. A repetition of the description of these elements and the related purposes or usage is omitted for simplicity.

For the embodiments of FIGS. 5 and 6, the plasma may be generated in the injector assembly. In one embodiment, the plasma may be generated in the vertical channel inside the injector assembly. Also, the vertical channel may be denoted as plenum or cavity.

FIG. 5 shows a batch processing chamber 500. The injector assembly 550 includes vertical rods 553 insulated from each other by insulator parts 559. Alternatively, the injector 550 may be formed of an insulating material. A plasma power source 580 is connected to the top rod 553 and the bottom rod 553. According to one embodiment the top rod may be the cathode and the bottom rod may be the cathode, whereas to another embodiment the top rod may be the cathode whereas the bottom rod is the anode. The rods form electrodes for generation of a plasma. The generated plasma is confined in the vertically extending channels 555. The plasma is generated vertically and the excited species of the processing gas enter the process region horizontally through the openings in the faceplate of the injector assembly.

According to an alternative embodiment, the faceplate of the injector may be made of a conductive material to improve confinement of the plasma within the vertical channel. The embodiments described with respect to FIG. 5, may optionally include a diffuser 160 as shown in FIG. 5 and described in more detail with respect to FIGS. 1 and 2.

The embodiment shown in FIG. 6 also includes plasma generating elements that provide a plasma in the vertical channel of the injector assembly 650. The plasma is generated between the walls of the vertical channel. One wall is the faceplate 152 including the openings 153. The other wall is electrode 652 is provided in the body 651 of injector assembly 650. Electrode 652 forms the wall of the vertical channel opposing the faceplate 152. The two electrodes connected to the power supply 680 are separated by insulator element 659.

According to an alternative embodiment (not shown), the body 651 of the injector assembly may form one of the electrodes to generate the plasma. The injector is formed of a conductive material and no separate electrode 652 may be required. According to this embodiment, the faceplate forming the opposing electrode would also be connected to the body 651 by insulating elements 659. The embodiments described with respect to FIG. 6, may optionally include a diffuser 160 as shown in FIG. 5 and described in more detail with respect to FIGS. 1 and 2.

Embodiments described herein with respect to FIGS. 1 to 6 illustrate batch processing chambers which may be used during plasma assisted processes, e.g., ALD or CVD processes. Therein, the plasma assistance provides ionized species of the processing gases within the chamber and in or in the vicinity of the process region. The presence of the plasma in the process region or in the vicinity of the process region reduces relaxation of the excited states. Since the plasma assistance provides ionized species of the processing gases to the substrate surfaces, a plasma assisted process can be considered one form of process based on excited species of the processing gases.

In the following, another form of processes with assistance of exciting species and respective embodiments of chambers will be described. The processes, such as ALD processes or CVD processes, are assisted by UV radiation. The UV light may be used to excite and/or ionize species of the processing gases or, e.g., to maintain the O₃ concentration at a desired level. In light of the excitation of species of processing gases, i.e., the electrons are excited to higher excitation levels, UV assistance during batch processing may also be considered one form of process that is assisted by excited species.

On irradiation of the processing gases with UV light, species of the processing gases are excited above ground state. The excitation depends on the wavelength of the UV light. The wavelength may be in the range of 126 nm to 400 nm. The excited species assist ALD or CVD processes by initiating or enhancing surface reactions of the precursors or reactance. The enhancement may result in reduction of exposure time and, thus, increase throughput. Additionally, film quality may improve because of more complete reactions of the precursors.

For UV assisted film growth processes, the relaxation time of the excited species may be in a range that by the time the processing gas reaches the process region a remotely excited processing gas has relaxed. For example, the O₃ concentration might decrease by the time it reaches the process region of the deposition chamber if excited at a remote location. The O₃ concentration may be maintained higher by activating O₃ inside the chamber.

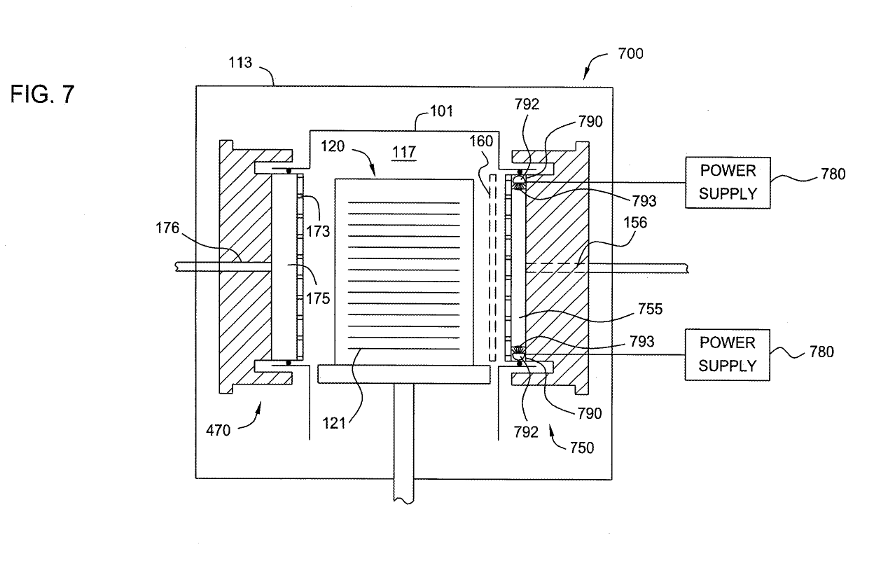

An embodiment of a batch processing chamber 700 with UV assistance is shown in FIG. 7. Within FIG. 7, elements that are the same in the embodiments of FIG. 1 or other previous embodiments are denoted with the same reference numbers. Alternatively, these elements may be the same as in the embodiment shown in FIG. 2. A repetition of the description of these elements and the related purposes or usage is omitted for simplicity.

FIG. 7 illustrates an embodiment for irradiating UV light vertically inside the vertical channel 755 of the injector assembly 750. A UV source 790 is provided at the upper end of the vertical channel 755 and a UV source is provided at the lower end of the vertical channel. Each source includes a lamp 792 and a window 793 facing the vertical channel. The window material can be chosen depending from the UV wavelength. For example a quartz window may be used for wavelength up to about 180 nm to 220 nm. Sapphire, magnesium fluoride or calcium fluoride windows may be used as window 793 in the event of shorter wavelengths.

The UV light extends vertically along the vertical channel 755 and excites species of the processing gases in the injector assembly before entering the process region. Within the embodiment shown in FIG. 7, UV lamps like deuterium lamps or arc lamps filled with Hg or Xe, may be used. The species of the processing gas excited in the vertical channel are provided uniformly with the uniform gas flow generated by the injector assembly, the exhaust assembly and optionally be the diffuser, the gas flow being described in more detail with respect to FIG. 1.

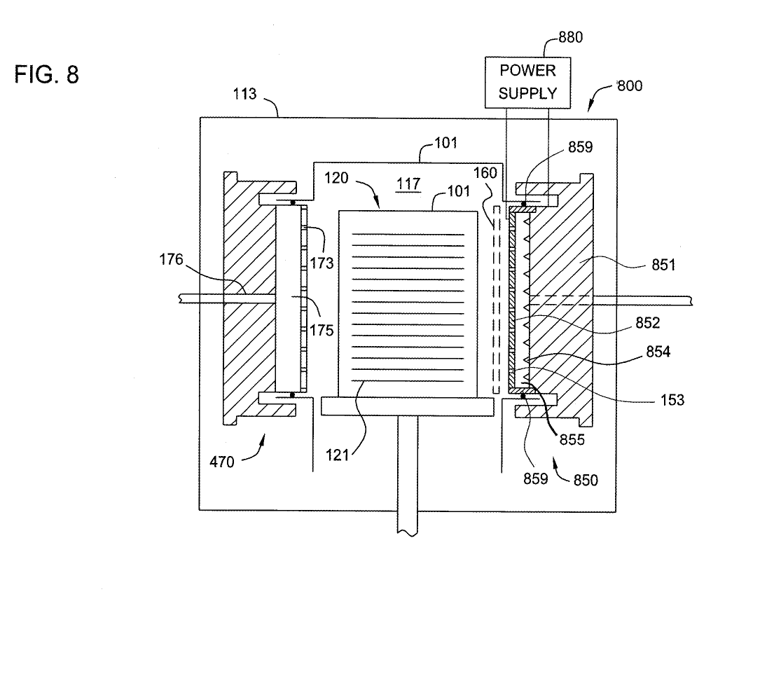

FIG. 8 shows another embodiment of batch processing chamber 800 with an injector assembly 850. The embodiment may be used for UV assisted processes. Within FIG. 8, elements that are the same in the embodiments of FIG. 1 or other previous embodiments are denoted with the same reference numbers. Alternatively, these elements may be the same as in the embodiment shown in FIG. 2. A repetition of the description of these elements and the related purposes or usage is omitted for simplicity.

FIG. 8 illustrates that the injector assembly shines UV light through openings 153 of the faceplate horizontally and parallel to substrate surfaces of substrates stacked in a substrate boat. The UV light is generated in the vertical channel 855 by striking a glow discharge with a noble gas in vertical channel 855. The injector face 852 of the faceplate is configured as an anode. The body 851 of the injector is electrically insulated by insulators 859 from the anode. The vertical channel 855 functions as a hollow cathode.

As described with previously with respect to FIG. 2, the injector assembly may have a plurality of vertical channels. A single one of the vertical channels or a plurality of vertical channels may be used as a hollow cathode to provide UV light inside the chamber.

In the event the electrical field in the injector may be too small to strike a glow discharge, tips 854 can be mounted in the injector. Thereby, the electrical field strength near the tips is increased and the glow discharge can be ignited with smaller voltages applied. According to another embodiment (not shown) the tips 854 may be omitted if sufficient power is provided by power source 880 to strike the glow discharge in the vertical channel.

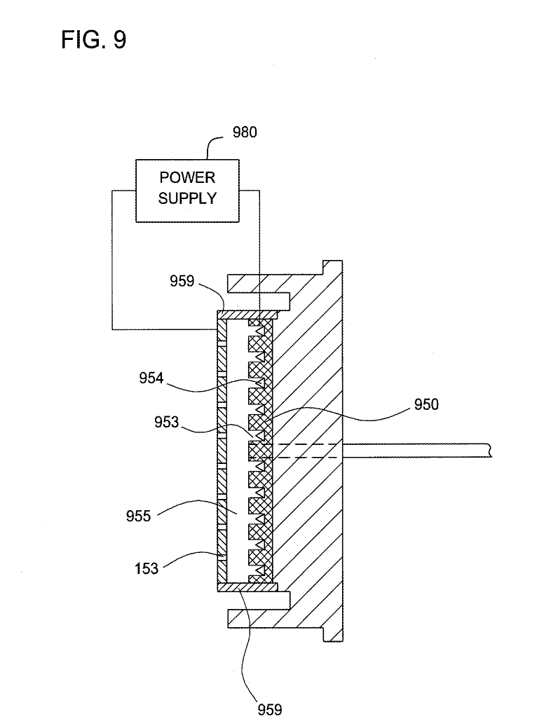

FIG. 9 shows another embodiment of an injector assembly. As compared to the embodiment shown in FIG. 8, a separate conductive element 950 is provided at the rear end of the vertical channel 955 as the cathode. The cathode 950 is provided with a plurality of small cavities. These cavities are in the form of cylinders with a small diameter in the range of 1 mm to 12 mm, are provided as an array of additional hollow cathodes. Thereby, the hollow cathode effect providing the UV light with a wavelength corresponding to the gas in the vertical channel 955 and/or the cathode material can be multiplied. As a result, the photon density in the vertical channel 955 and in the process region wherein the substrates are processed can be increased. Alignment between hollow cathodes and the faceplate holes ensures that transmission into the process region is optimized.

Tips 954 may be provided in the hollow cathodes. The tips may be used to increase the electrical field strength due to the small curvature of the tip and improve striking of a glow discharged at lower voltage levels.

According to another embodiment (not shown) a glow discharge may also be generated between the diffuser and the face of the injector that is one side of the faceplate. Thereby, the diffuser is provided as the anode and the face of the injector is the cathode.

For all embodiments where the glow discharge is contained in a plenum of the injector for UV production, differential pumping may used (not shown). In some instances, the process pressure at the substrates may be lower than the pressure required by the glow discharge used for UV production. In this case, gas used for glow discharge may be diverted from the process chamber.

For all embodiments where the glow discharge is contained in a plenum of the injector for UV production, an UV transparent membrane may be fastened to the reactor side of the injector faceplate (not shown.) In some instances, the process pressure at the substrates may be higher than the pressure required by the glow discharge used for UV production. In this case, gas from the process is isolated from the gas used for glow discharge by a barrier. Since the barrier is UV transparent, UV is transmitted to the substrates. The barrier is thin to enhance UV transmission, but thick enough to support a process pressure of up to about 10 Torr.

Generally, for the UV assisted batch processing chambers, the wavelength of the UV radition, that is the photon energy, may be selected based on the gases used in the hollow cathode. Typical noble gases and corresponding irradiated photon energy based on recombination of the excited states are He (for example, 21.22 eV, 40.82 eV, 40.38 eV), Ne (for example, 16.85 eV, 16.67 eV, 26.9 eV) or Ar (for example, 11.83 eV, 11.63 eV, 13.48 eV, 13.30 eV). Broad spectrum UV from deuterium lamps, or other UV sources (for example a mercury lamp), as well as softer UV radiation is also applicable.

For UV assisted batch processing chambers, a susceptor for carrying the substrates formed of silicon carbide (SiC) may be adapted to reflect the UV light. The susceptor profile and the roughness may be adapted to reflectively focus the UV light on the substrate surfaces. Thereby, a location of excitation of processing gas species by UV radiation may be even closer to the substrate surfaces. The cylindrical geometry of the inner chamber 101 favors glancing angles for which UV reflectivity is enhanced relative to normal incidence. With a glow discharge in the injector vertical channel, UV radiation may be provided during any process step having appropriate conditions for the glow discharge. As mentioned above, conditions in the plenum of the injector and the processing region may vary if a gas diversion, a barrier or other measures are provided. Thereby, conditions appropriate for glow discharge may be provided in the parts of the chamber. Appropriate process conditions may include the injection of a gas desired for the glow discharge. For 11.63 eV and 11.83 eV photons from Ar, an optimal pressure of the glow discharge is 0.45 Torr, and the reflectivity for SiC is 0.4 at normal incidence and at π/4 incidence.

For CVD processes that require UV assistance, the expected duty cycle is continuous. For ALD processes, there are several instances for which UV assistance may be required for film properties and/or for throughput. UV assistance may be required for one or all precursor exposures where the photon energy may be required to start the reaction between precursor molecule and surface binding site. UV assistance may be required during the cycle-purging steps at the end of an ALD cycle to complete the surface reaction such that incorporation of reaction byproducts is minimized.

The following embodiments will be described while making reference to FIGS. 8 and 9. As described above, UV assisted processes can be provided with a vertically extending anode and a vertically extending hollow cathode, wherein the anode and the cathode are arranged such that the anode is closer to the substrate boat holding the wafer stack.

The embodiments described above with respect to the plasma assisted processes and the hollow cathode effect may also be utilized for ion assisted ALD or CVD batch processing chambers. Therefore, according to one embodiment, a diffuser would be the cathode and the injector face would be the anode. According to another embodiment, the injector face side of the vertical channel (faceplate side of the vertical channel) would be the cathode and the opposing side of the injector located towards the body of the injector assembly would be the anode. Generally, the power supply 980 is connected to the respective components of the previous embodiments with a polarization, such that ions are provided to the processing region. In light of the ionization of species of processing gases, ion generating assistance during batch processing may also be considered one form of process assisted by excited species. Further, the diffuser may be modified to provide a hollow cathode effect.

Ions generated in the glow discharge are then accelerated towards the process region. Ions and neutrals may pass the cathode through openings provided therein. Thus, the ions and neutrals enter the process region and can assisted processes by the energy or the momentum of the ions. The kinetic energy of the ions and neutrals may be about 600 eV. Optionally retarding grids may be used to reduce the ion energy. A retarding grid may be provided in form of a mesh with a potential applied thereto. The potential decelerates the ions. The decelerated ions may pass through openings in the grid. A charged grid mounted between the injector and the wafer boat can, thus, reduce the energy and the momentum to a desired level.

For the embodiments relating to plasma assisted processes, UV assisted processes or ion assisted processes, the electrode formed by the elements of the injector and the exhaust may be grounded, whereas the other electrode is biased. Elements of the injector or exhaust assembly may be an anode or a cathode for plasma generation, UV generation or ion generation. Generally, it is to be understood that either one of the anode or the cathode may be grounded.

### Processes for Depositing Materials

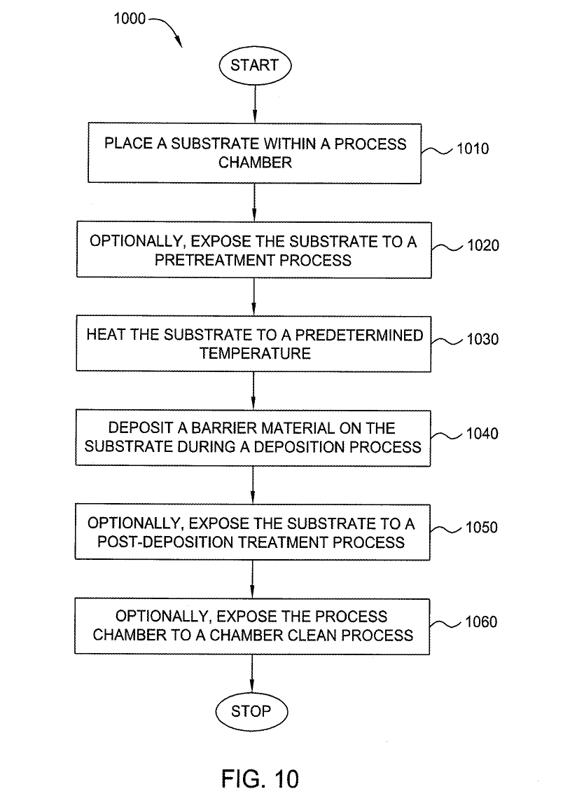

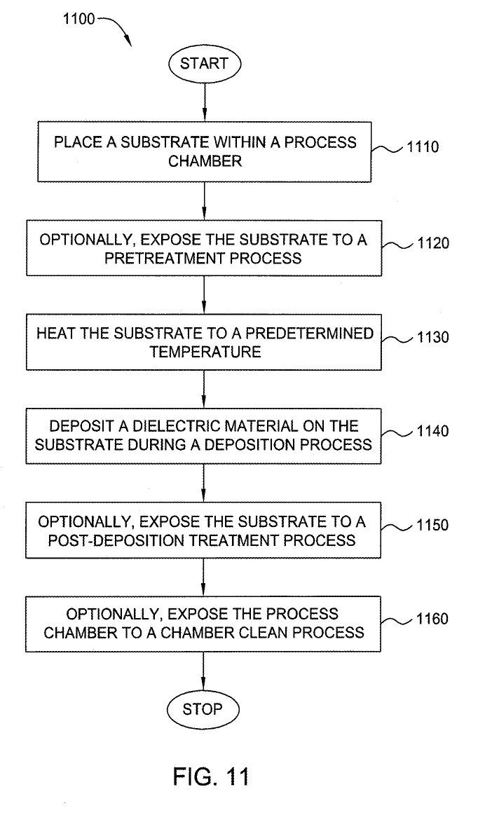

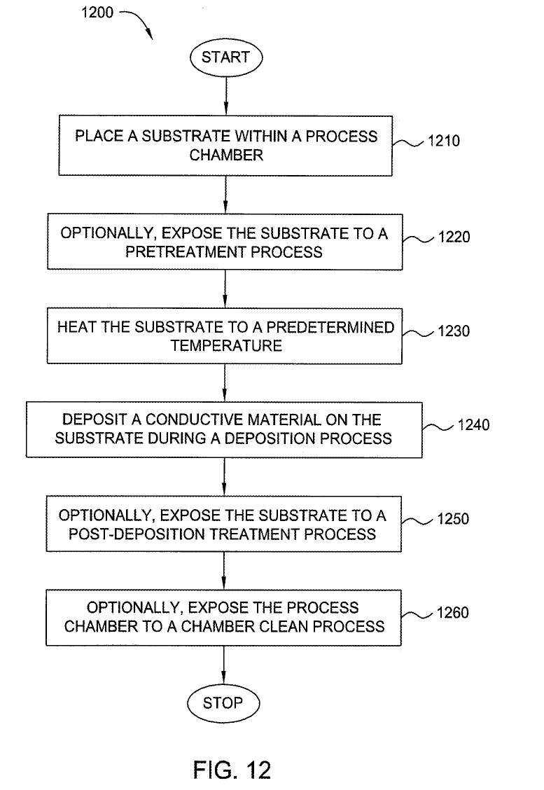

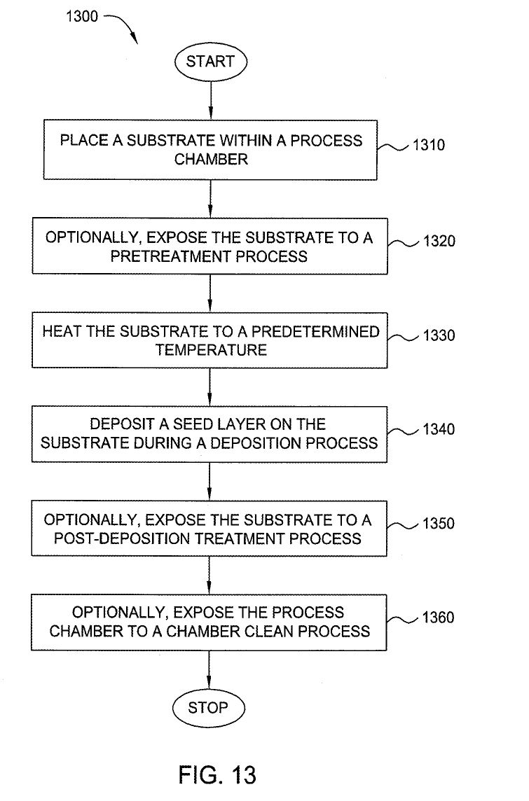

FIGS. 10-13 illustrate flow chart diagrams of processes 1000, 1100, 1200, and 1300 for depositing materials with UV assisted photoexcitation, as described by embodiments herein. Processes 1000, 1100, 1200, and 1300 may be performed with process chamber 600, such as described by examples herein, or by other suitable chamber and equipment. One such suitable chamber is described in co-pending U.S. patent application Ser. No. 11/157,567, filed Jun. 21, 2005, entitled METHOD FOR TREATING SUBSTRATES AND FILMS WITH PHOTOEXCITATION, which is herein incorporated by reference to the extent it does not conflict with the current specification. The processes described herein may be used to deposit barrier materials (FIG. 10) such as Ta and TaN, dielectric materials (FIG. 11) such as RuO₂, IrO₂, Ir₂O₃, ZrO₂, HfO₂, Al₂O₃, Ta₂O₅, TiO₂, RhO₂, PdO, OsO, PtO, VO, V₂O₅, V₂O₃, V₆O₁₁, Ba(Sr)TiO₃ (BST), Pb(ZrTi)O₃ (PZT), SrBi₂Ta₂O₉ (SBT), Ln₂O₃, and their silicates, conductive materials (FIG. 12) such as WN, TiN, and Cu and seed layer materials (FIG. 13) such as Ru, Ir, W, Ta, TaN, Rh, and Pt. Other materials that may be deposited using the precursors and processes described herein include nitrides, such as boron nitride, hafnium nitride, aluminum nitride, and zirconium nitride, and metal borides such as magnesium boride, vanadium boride, hafnium boride, titanium boride, tungsten boride, and tantalum boride. The materials may be deposited as layers on a substrate to form electronic features such as integrated circuits.

### Barrier Materials

FIG. 10 depicts a flow diagram of process 1000 for depositing a barrier material, as described by embodiments herein. The substrate may be positioned within a process chamber (step 1010), optionally exposed to a pretreatment process (step 1020), and heated to a predetermined temperature (step 1030). Subsequently, a barrier material may be deposited on the substrate (step 1040). The substrate may be optionally exposed to a post-deposition treatment process (step 1050) and the process chamber may be optionally exposed to a chamber clean process (step 1060).

The substrate may be positioned within a process chamber during step 1010. The process chamber may be a single wafer chamber or a batch chamber containing multiple wafers or substrates (e.g., 25, 50, 100, or more). The substrate may be maintained in a fixed position, but preferably, is rotated by a support pedestal. Optionally, the substrate may be indexed during one or more steps of process 1000.

Process chamber 600, depicted in FIG. 7, may be used during process 1000 to deposit barrier materials on substrate 121 as described by examples herein. In one example, substrate 121 may be rotated on a substrate support pedestal within process chamber 600 at a rate of up to about 120 rpm (revolutions per minute). Alternatively, substrate 121 may be positioned on substrate support pedestal and not rotated during the deposition process.

In one embodiment, the substrate 121 is optionally exposed to at least one pretreatment process during step 1020. The substrate surface may contain native oxides that are removed during a pretreatment process. The substrate may be pretreated with an energy beam generated by a direct photoexcitation system to remove the native oxides from the substrate surface prior to depositing a barrier material during step 1040. A process gas may be exposed to the substrate during the pretreatment process. The process gas may contain argon, nitrogen, helium, hydrogen, forming gas, or combinations thereof. The pretreatment process may last for a time period within a range from about 2 minutes to about 10 minutes to facilitate native oxide removal during a photoexcitation process. Also, the substrate 121 may be heated during step 1020 to a temperature within a range from about 100° C. to about 800° C., preferably, from about 200° C. to about 600° C., and more preferably, from about 300° C. to about 500° C., to facilitate native oxide removal during process 1000.

Examples provide that substrate 121 may be exposed to an energy beam produced by lamp 792 during step 1020. Lamp 792 may provide an energy beam having a photon energy within a range from about 2 eV to about 10 eV, for example from about 3.0 eV to about 9.84 eV. In another example, lamp 792 provides an energy beam of UV radiation having a wavelength within a range from about 123 nm to about 500 nm. Lamp 792 may be energized for a period sufficient to remove oxides. The energization period is selected based upon the size and geometry of window 793 and the substrate rotation speed. In one embodiment, lamp 792 is energized for a time period within a range from about 2 minutes to about 10 minutes to facilitate native oxide removal during a photoexcitation process. In one example, substrate 121 may be heated to a temperature within a range from about 100° C. to about 800° C. during step 1020. In another example, substrate 121 may be heated to a temperature within a range from about 300° C. to about 500° C. during step 1020, while lamp 792 provides an energy beam having a photon energy within a range from about 2 eV to about 10 eV for a time period within a range from about 2 minutes to about 5 minutes to facilitate native oxide removal. In one example, the energy beam has a photon energy within a range from about 3.2 eV to about 4.5 eV for about 3 minutes.

In another embodiment, native oxide removal may be augmented by a photoexcitation process in the presence of a process gas containing an energy delivery gas during a pretreatment process at step 1020. The energy delivery gas may be neon, argon, krypton, xenon, argon bromide, argon chloride, krypton bromide, krypton chloride, krypton fluoride, xenon fluorides (e.g., XeF₂), xenon chlorides, xenon bromides, fluorine, chlorine, bromine, excimers thereof, radicals thereof, derivatives thereof, or combinations thereof. In some embodiments, the process gas may also contain nitrogen gas (N₂), hydrogen gas (H₂), forming gas (e.g., N₂/H₂ or Ar/H₂) besides at least one energy delivery gas.

In one example, substrate 121 may be exposed to a process gas containing an energy delivery gas by providing the process gas to inner chamber 101 of process chamber 600 during step 1020. The energy delivery gas may be provided through faceplate 152 from gas source 159. The proximity of the process gas to lamp 792 compared to substrate 121 readily excites the energy delivery gas therein. As the energy delivery gas de-excites and moves closer to substrate 121, the energy is efficiently transferred to the surface of substrate 121, thereby facilitating the removal of native oxides.

In another embodiment, native oxide removal may be augmented by a photoexcitation process in the presence of a process gas containing an organic vapor during the pretreatment process at step 1020. In one example, the substrate may be exposed to the process gas containing a cyclic aromatic hydrocarbon. The cyclic aromatic hydrocarbon may be in the presence of UV radiation. Monocyclic aromatic hydrocarbons and polycyclic aromatic hydrocarbons that are useful during a pretreatment process include quinone, hydroxyquinone (hydroquinone), anthracene, naphthalene, phenanthracene, derivatives thereof, or combinations thereof. In another example, the substrate may be exposed to the process gas containing other hydrocarbons, such as unsaturated hydrocarbons, including ethylene, acetylene (ethyne), propylene, alkyl derivatives, halogenated derivates, or combinations thereof. In another example, the organic vapor may contain alkane compounds during the pretreatment process at step 1020.

In one example, the UV radiation having a wavelength within a range from about 123 nm to about 500 nm may be generated by a lamp during step 1020. In another embodiment, polycyclic aromatic hydrocarbons may remove native oxides in the presence of UV radiation by reacting with oxygen atoms within the native oxides. In another embodiment, native oxides may be removed by exposing the substrate to quinone or hydroxyquinone while forming derivative products. The derivative product may be removed from the process chamber by a vacuum pumping process.

At step 1030, the substrate 121 may be heated to a predetermined temperature during or subsequent to the pretreatment process. The substrate 121 is heated prior to depositing the barrier material at step 1040. The substrate may be heated by an embedded heating element within the substrate support, the energy beam (e.g., UV-source), or combinations thereof. Generally, the substrate is heated long enough to obtain the predetermined temperature, such as for a time period within a range from about 15 seconds to about 30 minutes, preferably, from about 30 seconds to about 20 minutes, and more preferably, from about 1 minute to about 10 minutes. In one embodiment, the substrate may be heated to a temperature within a range from about 200° C. to about 1,000° C., preferably, from about 400° C. to about 850° C., and more preferably, from about 550° C. to about 800° C. In another embodiment, the substrate may be heated to a temperature of less than about 550° C., preferably, less than about 450° C.

In one example, substrate 121 may be heated to the predetermined temperature within process chamber 600. The predetermined temperature may be within a range from about 300° C. to about 500° C. Substrate 121 may be heated by applying power from a power source to a heating element, for example heater block 211.

In one embodiment, a barrier material is deposited on the substrate during a deposition process at step 1040. The barrier material may comprise for example, one or more layers of titanium (Ti), titanium nitride (TiN), tantalum (Ta), tantalum nitride (TaNₓ), tungsten (W), or tungsten nitride (WNₓ), among others, on the substrate. The barrier layer material may be formed by exposing the substrate to at least one deposition gas during the deposition process. In one example, the deposition process is a CVD process having a deposition gas that may contain a tantalum precursor, titanium precursor, or a tungsten precursor and a nitrogen precursor or a precursor containing both sources. Using CVD techniques, the one or more barrier layers may be formed by thermally decomposing the aforementioned precursors. Alternatively, the deposition process may be an ALD process having at least two deposition gases, such that, the substrate is sequentially exposed to a tantalum precursor, titanium precursor, or a tungsten precursor and a nitrogen precursor. The deposition process may be a thermal process, a radical process, or a combination thereof. For example, the substrate may be exposed to a process gas in the presence of an energy beam generated by a direct photoexcitation system.

Nitrogen (N₂) gas is provided to the processing chamber when a nitride based barrier layer is to be formed such as TiNₓ, TaNₓ or WNₓ. The N₂ gas flow rate may be in a range of about 100 sccm to about 2000 sccm. Examples of suitable nitrogen precursors for forming barrier materials at step 1040 include ammonia (NH₃), hydrazine (N₂H₄), organic amines, organic hydrazines, organic diazines (e.g., methyldiazine ((H₃C)NNH)), silylazides, silylhydrazines, hydrogen azide (HN₃), hydrogen cyanide (HCN), atomic nitrogen (N), nitrogen (N₂), derivatives thereof, or combinations thereof. Organic amines as nitrogen precursors include RₓNH₃₋ₓ, where each R is independently an alkyl group or an aryl group and x is 1, 2, or 3. Examples of organic amines include trimethylamine ((CH₃)₃N), dimethylamine ((CH₃)₂NH), methylamine ((CH₃)NH₂)), triethylamine ((CH₃CH₂)₃N), diethylamine ((CH₃CH₂)₂NH), ethylamine ((CH₃CH₂)NH₂)), tertbutylamine (((CH₃)₃C)NH₂), derivatives thereof, or combinations thereof. Organic hydrazines as nitrogen precursors include RₓN₂H₄₋ₓ, where each R is independently an alkyl group or an aryl group and x is 1, 2, 3, or 4. Examples of organic hydrazines include methylhydrazine ((CH₃)N₂H₃), dimethylhydrazine ((CH₃)₂N₂H₂), ethylhydrazine ((CH₃CH₂)N₂H₃), diethylhydrazine ((CH₃CH₂)₂N₂H₂), tertbutylhydrazine (((CH₃)₃C)N₂H₃), ditertbutylhydrazine (((CH₃)₃C)₂N₂H₂), radicals thereof, plasmas thereof, derivatives thereof, or combinations thereof.

The tungsten precursor may be selected from tungsten hexafluoride (WF₆) and tungsten carbonyl (W(CO)₆). The tantalum-containing precursor may be selected, for example, from the group of tantalum pentachloride (TaCl₅), pentakis(diethylamido) tantalum (PDEAT) (Ta(Net₂)₅), pentakis (ethylmethylamido) tantalum (PEMAT) (Ta(N(Et)(Me))₅), and pentakis(dimethylamido) tantalum (PDMAT) (Ta(Nme₂)₅), among others. The titanium-containing precursor may be selected, for example, from the group of titanium tetrachloride (TiCl₄), tetrakis(diethylamido) titanium (TDEAT) (Ti(Net₂)₄), tetrakis(ethylmethylamido) titanium (TEMAT) (Ti(N(Et)(Me))₄), and tetrakis(dimethylamido) titanium (TDMAT) (Ti(NMe₂)₄), among others.

Suitable reducing gases may include traditional reductants, for example, hydrogen (e.g., H₂ or atomic-H), ammonia (NH₃), silane (SiH₄), disilane (Si₂H₆), trisilane (Si₃H₈), tetrasilane (Si₄H₁₀), dimethylsilane (SiC₂H₈), methyl silane (SiCH₆), ethylsilane (SiC₂H₈), chlorosilane (ClSiH₃), dichlorosilane (Cl₂SiH₂), hexachlorodisilane (Si₂Cl₆), borane (BH₃), diborane (B₂H₆), triborane, tetraborane, pentaborane, alkylboranes, such as triethylborane (Et₃B), derivatives thereof and combinations thereof.

In one example, a barrier material may be deposited on substrate 121 within process chamber 600 during a deposition process at step 1040. In one embodiment, substrate 121 may be exposed to a process gas containing a tungsten precursor, a titanium-containing precursor, or a tantalum-containing precursor and a nitrogen precursor during a CVD process. The precursors are generally provided from gas source 159 to inner chamber 101 through faceplate 152.

In one embodiment, the precursors may be introduced at step 1040 into the process chamber 600 or exposed to substrate 121 by inlet channel 156 simultaneously, such as during a traditional CVD process or sequentially, such as during an ALD process. The ALD process may expose the substrate 121 to at least two deposition gases, such that, the substrate 121 is sequentially exposed to a first precursor such as a tungsten containing precursor, a titanium-containing precursor, or a tantalum-containing precursor and a second precursor such as a nitrogen precursor. When depositing a tungsten layer it is contemplated that the first precursor is a tungsten-containing precursor such as WF₆ and the second precursor is a reducing gas such as B₂H₆. Although one inlet channel 156 is shown, it is contemplated that the first precursor and the second precursor are provided to process chamber 600 in separate gas lines. The temperature may be controlled for each gas line.

A description of CVD and ALD processes and apparatuses that may be modified (e.g., incorporating a UV radiation source) and chemical precursors that may be useful for depositing barrier materials are further disclosed in commonly assigned U.S. Pat. No. 6,833,161, issued Dec. 21, 2004, entitled CYCLICAL DEPOSITION OF TUNGSTEN NITRIDE FOR METAL OXIDE GATE ELECTRODE, U.S. Pat. No. 6,951,804, issued Oct. 4, 2005, entitled FORMATION OF TANTALUM NITRIDE LAYER, U.S. Pat. No. 7,049,226, issued May 23, 2006, entitled INTEGRATION OF ALD TANTALUM NITRIDE FOR COPPER METALLIZATION, U.S. Pat. No. 6,607,976, issued Aug. 19, 2003, entitled COPPER INTERCONNECT BARRIER LAYER STRUCTURE AND FORMATION METHOD, U.S. Pat. No. 6,911,391, issued Jun. 28, 2005, entitled INTEGRATION OF TITANIUM AND TITANIUM NITRIDE LAYERS, and U.S. Pat. App. Pub. No. 2003-0108674, published Jun. 12, 2003, entitled CYCLICAL DEPOSITION OF REFRACTORY METAL SILICON NITRIDE, U.S. Pat. App. Pub. No. 2006-0009034, published Jan. 12, 2006, entitled METHODS FOR DEPOSITING TUNGSTEN LAYERS EMPLOYING ATOMIC LAYER DEPOSITION TECHNIQUES, which are all herein incorporated by reference in their entirety.

For example, when a titanium containing precursor and a nitrogen precursor are combined in the process chamber, a titanium-containing material, such as a titanium nitride, is formed on the substrate surface. The deposited titanium nitride material exhibits good film qualities such as reflective index and wet etch rate. In one embodiment, the titanium nitride material may be deposited at a rate within a range from about 10 Å/min to about 500 Å/min and is deposited to a thickness within a range from about 10 Å to about 1,000 Å.

A carrier gas may be provided during step 1040 to control the partial pressure of the nitrogen precursor and the titanium precursor. The total internal pressure of a single wafer process chamber may be at a pressure within a range from about 100 mTorr to about 740 Torr, preferably, from about 250 mTorr to about 100 Torr, and more preferably, from about 500 mTorr to about 50 Torr. In one example, the internal pressure of the process chamber is maintained at a pressure of about 10 Torr or less, preferably, about 5 Torr or less, and more preferably, about 1 Torr or less. In some embodiments, the carrier gas may be provided to control the partial pressure of the nitrogen precursor or the silicon precursor within a range from about 100 mTorr to about 1 Torr for batch processing systems. Examples of suitable carrier gases include nitrogen, hydrogen, argon, helium, forming gas, or combinations thereof.

The substrate, the first precursor, and/or the second precursor may be exposed to an energy beam or a flux of energy generated by the photoexcitation system during the deposition process at step 1040. The use of the energy beam advantageously increases the deposition rate and improves surface diffusion or mobility of atoms within the barrier material to create active sites for incoming reactive species. In one embodiment, the beam has energy within a range from about 3.0 eV to about 9.84 eV. Also, the energy beam may have a wavelength within a range from about 123 nm to about 500 nm.

In one example, lamp 792 provides an energy beam to supply the excitation energy of at least one of the first precursor or the nitrogen precursor. The high deposition rate and the low deposition temperature produce a film having tunable properties with minimal parasitic side reactions. In one embodiment, the energy beam or flux may have a photon energy within a range from about 4.5 eV to about 9.84 eV.

In another embodiment, the substrate containing the barrier material (formed in step 1040) is exposed to a post-deposition treatment process during step 1050. The post-deposition treatment process increases the substrate surface energy after deposition, which advantageously removes volatiles and/or other film contaminants (such as by reducing the hydrogen content) and/or anneals the deposited film. A lower concentration of hydrogen from the deposited material advantageously increases tensile stress of the film. At least one lamp (e.g., lamp 790) may alternatively be utilized to energize an energy delivery gas which is exposed to the substrate to increase the surface energy of the substrate after deposition and to remove volatiles and/or other films.

Optionally, at step 1050, an energy delivery gas may be provided to inner chamber 101 of process chamber 600. Examples of suitable energy delivery gases include nitrogen, hydrogen, helium, argon, and combinations thereof. Examples provide that substrate 121 is treated with an energy beam or flux of energy during step 1050. In one example, lamp 792 provides an energy beam to supply the surface energy of substrate 121 during step 1050. In another example for annealing the barrier material, the energy beam or flux may have a photon energy within a range from about 3.53 eV to about 9.84 eV. Also, lamp 790 may produce an energy beam having a wavelength within a range from about 123 nm to about 500 nm. Generally, lamp 790 may be energized for a time period within a range from about 1 minute to about 10 minutes to facilitate post deposition treatment by photoexcitation.

In one example, volatile compounds or contaminants may be removed from the deposited film surface by exposing the substrate to an energy beam generated by lamp 790 having a photon energy within a range from about 3.2 eV to about 4.5 eV is utilized to dissociate radicals within process chamber 600. Thus, excimer lamps, such as XeBr* (283 nm/4.41 eV), Br₂* (289 nm/4.29 eV), XeCl* (308 nm/4.03 eV), I₂* (342 nm/3.63 eV), XeF* (351 nm/3.53 eV) may be selected to dissociate the N—H bonds to remove hydrogen from the TiN, TaN, and WN networks. It is contemplated that the rotational speed of the substrate may be changed, for example, by increasing the rotation speed in step 1050 relative to the preceding deposition step.

In another embodiment, the substrate 121 may be removed from the process chamber 600 and the process chamber 600 is subsequently exposed to a chamber clean process during step 1060. The process chamber may be cleaned using a photoexcited cleaning agent. In one embodiment, the cleaning agent includes fluorine. Examples provide that the cleaning agent may be photoexcited within process chamber 600 using lamp 790.

Process chamber 600 may be cleaned during a chamber clean process to enhance deposition performance. For example, the chamber clean process may be used to remove contaminants contained on the surfaces of process chamber 600 or contaminants contained on windows 793, thereby minimizing transmission losses of the energy beam or flux traveling through window 793 and maximizing the energy transferred to the gases and surfaces. Window 793 may be cleaned with greater frequency than process chamber 600, for example, process chamber 600 may be cleaned after processing a number of substrates while window 793 is cleaned after processing each substrate. Suitable cleaning agents include, for example, H₂, HX (where X═F, Cl, Br, or I), NX₃ (where X═F or Cl), interhalogen compounds such as XFₙ (where X═Cl, Br, I and n=1, 3, 5, 7) and its hydrogenated inter-halogen compounds, and inert gas halides such as XeF₂, XeF₄, XeF₆, and KrF₂.

The elemental composition of the barrier material deposited during step 1040 may be predetermined by controlling the concentration or flow rate of the chemical precursors. Film properties may be tailored for specific applications by controlling the relative concentrations of Ta, Ti, W, H, and N₂ within the barrier material. In one embodiment, the elemental concentrations of Ta, Ti, W, H, and N₂ may be tuned by varying the range of the UV energy during or subsequent to the deposition process. The film properties include wet etch rate, dry etch rate, stress, dielectric constant, and the like. For example, by reducing the hydrogen content, the deposited material may have a higher tensile stress. In another example, by reducing the carbon content, the deposited material may have a lower electrical resistance.

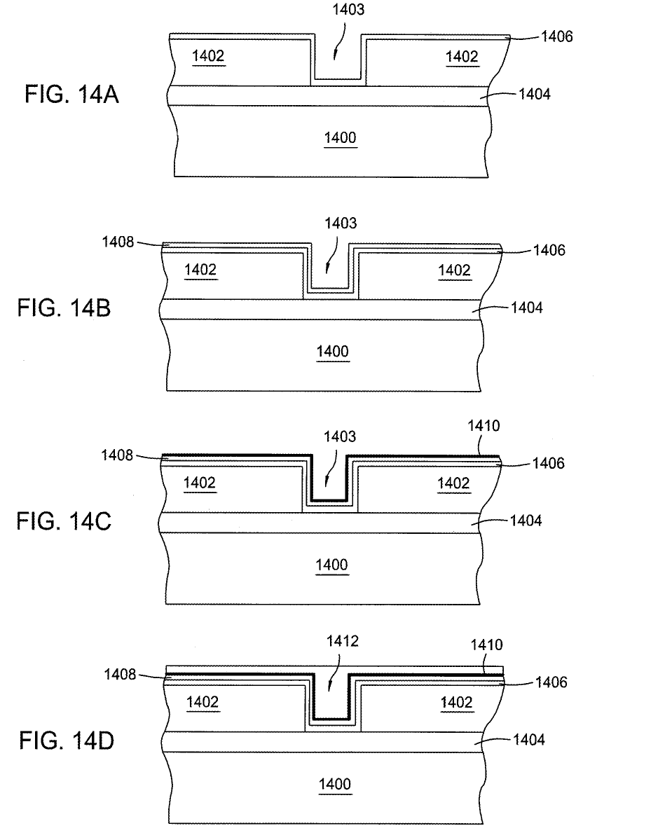

Barrier materials deposited during process 1000 as described herein may be used throughout electronic features/devices due to several physical properties. The barrier properties inhibit ion diffusion between dissimilar materials or elements when a barrier material is placed therebetween, such as a gate material and an electrode, or between low dielectric constant porous materials and copper. In one embodiment, barrier materials may be deposited during process 1000 as layers on a substrate to form electronic features, such as an integrated circuit (FIG. 14).

### Dielectric Materials

FIG. 11 depicts a flow diagram of process 1100 for depositing a dielectric material, as described by embodiments herein. The substrate may be positioned within a process chamber (step 1110), optionally exposed to a pretreatment process (step 1120), and heated to a predetermined temperature (step 1130). Subsequently, a dielectric material may be deposited on the substrate (step 1140). The substrate may be optionally exposed to a post-deposition treatment process (step 1150) and the process chamber may be optionally exposed to a chamber clean process (step 1160).

The substrate may be positioned within a process chamber during step 1110. The process chamber may be a single wafer chamber or a batch chamber containing multiple wafers or substrates (e.g., 25, 50, 100, or more). The substrate may be maintained in a fixed position, but preferably, is rotated by a support pedestal. Optionally, the substrate may be indexed during one or more steps of process 1100.

Process chamber 600, depicted in FIG. 7, may be used during process 1100 to deposit dielectric materials on substrate 121 as described by examples herein. In one example, substrate 121 may be rotated on a substrate support pedestal within process chamber 600 at a rate of up to about 120 rpm (revolutions per minute). Alternatively, substrate 121 may be positioned on substrate support pedestal and not rotated during the deposition process.

In one embodiment, the substrate 121 is optionally exposed to at least one pretreatment process during step 1120. The substrate surface may contain native oxides that are removed during a pretreatment process. The substrate 121 may be pretreated with an energy beam generated by a direct photoexcitation system to remove the native oxides from the substrate surface prior to depositing a dielectric material during step 1140. A process gas may be exposed to the substrate during the pretreatment process. The process gas may contain argon, nitrogen, helium, hydrogen, forming gas, or combinations thereof. The pretreatment process may last for a time period within a range from about 2 minutes to about 10 minutes to facilitate native oxide removal during a photoexcitation process. Also, the substrate 121 may be heated during step 1120 to a temperature within a range from about 100° C. to about 800° C., preferably, from about 200° C. to about 600° C., and more preferably, from about 300° C. to about 500° C., to facilitate native oxide removal during process 1100.

Examples provide that substrate 121 may be exposed to an energy beam produced by lamp 792 during step 1020. Lamp 792 may provide an energy beam having a photon energy within a range from about 2 eV to about 10 eV, for example from about 3.0 eV to about 9.84 eV. In another example, lamp 792 provides an energy beam of UV radiation having a wavelength within a range from about 123 nm to about 500 nm. Lamp 792 may be energized for a period sufficient to remove oxides. The energization period is selected based upon the size and geometry of window 793 and the substrate rotation speed. In one embodiment, lamp 792 is energized for a time period within a range from about 2 minutes to about 10 minutes to facilitate native oxide removal during a photoexcitation process. In one example, substrate 121 may be heated to a temperature within a range from about 100° C. to about 800° C. during step 1020. In another example, substrate 121 may be heated to a temperature within a range from about 300° C. to about 500° C. during step 1020, while lamp 792 provides an energy beam having a photon energy within a range from about 2 eV to about 10 eV for a time period within a range from about 2 minutes to about 5 minutes to facilitate native oxide removal. In one example, the energy beam has a photon energy within a range from about 3.2 eV to about 4.5 eV for about 3 minutes.

In another embodiment, native oxide removal may be augmented by a photoexcitation process in the presence of a process gas containing an energy delivery gas during a pretreatment process at step 1120. The energy delivery gas may be neon, argon, krypton, xenon, argon bromide, argon chloride, krypton bromide, krypton chloride, krypton fluoride, xenon fluorides (e.g., XeF₂), xenon chlorides, xenon bromides, fluorine, chlorine, bromine, excimers thereof, radicals thereof, derivatives thereof, or combinations thereof. In some embodiments, the process gas may also contain nitrogen gas (N₂), hydrogen gas (H₂), forming gas (e.g., N₂/H₂ or Ar/H₂) besides at least one energy delivery gas.

In one example, substrate 121 may be exposed to a process gas containing an energy delivery gas by providing the process gas to inner chamber 101 of process chamber 600 during step 1020. The energy delivery gas may be provided through faceplate 152 from gas source 159. The proximity of the process gas to lamp 792 compared to substrate 121 readily excites the energy delivery gas therein. As the energy delivery gas de-excites and moves closer to substrate 121, the energy is efficiently transferred to the surface of substrate 121, thereby facilitating the removal of native oxides.

In another embodiment, native oxide removal may be augmented by a photoexcitation process in the presence of a process gas containing an organic vapor during the pretreatment process at step 1120. In one example, the substrate may be exposed to the process gas containing a cyclic aromatic hydrocarbon. The cyclic aromatic hydrocarbon may be in the presence of UV radiation. Monocyclic aromatic hydrocarbons and polycyclic aromatic hydrocarbons that are useful during a pretreatment process include quinone, hydroxyquinone (hydroquinone), anthracene, naphthalene, phenanthracene, derivatives thereof, or combinations thereof. In another example, the substrate may be exposed to the process gas containing other hydrocarbons, such as unsaturated hydrocarbons, including ethylene, acetylene (ethyne), propylene, alkyl derivatives, halogenated derivates, or combinations thereof. In another example, the organic vapor may contain alkane compounds during the pretreatment process at step 1120.

In one example, the UV radiation having a wavelength within a range from about 123 nm to about 500 nm may be generated by a lamp during step 1120. In another embodiment, polycyclic aromatic hydrocarbons may remove native oxides in the presence of UV radiation by reacting with oxygen atoms within the native oxides. In another embodiment, native oxides may be removed by exposing the substrate to quinone or hydroxyquinone while forming derivative products. The derivative product may be removed from the process chamber by a vacuum pumping process.

At step 1130, the substrate 121 may be heated to a predetermined temperature during or subsequent to the pretreatment process. The substrate 121 is heated prior to depositing the dielectric material at step 1140. The substrate may be heated by an embedded heating element within the substrate support, the energy beam (e.g., UV-source), or combinations thereof. Generally, the substrate is heated long enough to obtain the predetermined temperature, such as for a time period within a range from about 15 seconds to about 30 minutes, preferably, from about 30 seconds to about 20 minutes, and more preferably, from about 1 minute to about 10 minutes. In one embodiment, the substrate may be heated to a temperature within a range from about 200° C. to about 1,000° C., preferably, from about 400° C. to about 850° C., and more preferably, from about 550° C. to about 800° C. In another embodiment, the substrate may be heated to a temperature of less than about 550° C., preferably, less than about 450° C.

In one example, substrate 121 may be heated to the predetermined temperature within process chamber 600. The predetermined temperature may be within a range from about 300° C. to about 500° C. Substrate 121 may be heated by applying power from a power source to a heating element, for example heater block 211.

In one embodiment, a dielectric material is deposited on the substrate during a deposition process at step 1140. The dielectric material may be formed by exposing the substrate to at least one deposition gas during the deposition process. In one example, the deposition process is a CVD process having a deposition gas that may contain a first precursor and an oxygen precursor or a precursor containing both the first precursor and oxygen precursor. Alternatively, the deposition process may be an ALD process having at least two deposition gases, such that, the substrate is sequentially exposed to a first precursor and an oxygen precursor. The deposition process may be a thermal process, a radical process, or a combination thereof. For example, the substrate may be exposed to a process gas in the presence of an energy beam by a direct photoexcitiation system.

The dielectric material contains oxygen and at least one metal, such as hafnium, zirconium, titanium, tantalum, lanthanum, ruthenium, aluminum or combinations thereof. The dielectric material may have a composition that includes hafnium-containing materials, such as hafnium oxides (HfOₓ or HfO₂), hafnium oxynitrides (HfOₓN_{y}), hafnium aluminates (HfAlₓO_{y}), hafnium lanthanum oxides (HfLaₓO_{y}), zirconium-containing materials, such as zirconium oxides (ZrOₓ or ZrO₂), zirconium oxynitrides (ZrOₓN_{y}) zirconium aluminates (ZrAlₓO_{y}) zirconium lanthanum oxides (ZrLaₓO_{y}) other aluminum-containing materials or lanthanum-containing materials, such as aluminum oxides (Al₂O₃ or AlOₓ), aluminum oxynitrides (AlOₓN_{y}), lanthanum aluminum oxides (LaAlₓO_{y}), lanthanum oxides (LaOₓ or La₂O₃), derivatives thereof or combinations thereof. Other dielectric materials may include titanium oxides (TiOₓ or TiO₂), titanium oxynitrides (TiOₓN_{y}), tantalum oxides (TaOₓ or Ta₂O₅) and tantalum oxynitrides (TaOₓN_{y}). Laminate films that are useful dielectric materials include HfO₂/Al₂O₃, La₂O₃/Al₂O₃ and HfO₂/La₂O₃/Al₂O₃. The dielectric material may also comprise for example, RuO₂, IrO₂, Ir₂O₃, ZrO₂, HfO₂, Al₂O₃, Ta₂O₅, TiO₂, Ba(Sr)TiO₃ (BST), Pb(ZrTi)O₃ (PZT), SrBi₂Ta₂O₉ (SBT), RhO₂, PdO, OsO, PtO, VO, V₂O₅, V₂O₃, V₆O₁₁, among others.

Examples of suitable oxygen precursors for forming dielectric materials during step 1140 include atomic oxygen (O), oxygen (O₂), ozone (O₃), water (H₂O), hydrogen peroxide (H₂O₂), organic peroxides, alcohols, nitrous oxide (N₂O), nitric oxide (NO), nitrogen dioxide (NO₂), dinitrogen pentoxide (N₂O₅), plasmas thereof, radicals thereof, derivatives thereof, or combinations thereof. In one embodiment, an oxygen precursor may be formed by combining ozone and water to provide a strong oxidizing agent. The oxygen precursor generally contains hydroxyl radicals (OH) which have strong oxidizing power. The ozone concentration may vary relative to the water concentration. A molar ratio of ozone to water ratio may be within a range from about 0.01 to about 30, preferably, from about 0.03 to about 3, and more preferably, from about 0.1 to about 1. In one example, an energy beam derived from a UV source may be exposed to oxygen or an oxygen/water mixture to form an oxygen precursor containing ozone. In another embodiment, the energy delivery gas and/or the atmosphere within the chamber during the photoexcitation step includes oxygen and/or ozone.

Exemplary hafnium precursors include hafnium compounds containing ligands such as halides, alkylaminos, cyclopentadienyls, alkyls, alkoxides, derivatives thereof or combinations thereof. Hafnium halide compounds useful as hafnium precursors may include HfCl₄, Hfl₄, and HfBr₄. Hafnium alkylamino compounds useful as hafnium precursors include (RR′N)₄Hf, where R or R′ are independently hydrogen, methyl, ethyl, propyl or butyl. Hafnium precursors useful for depositing hafnium-containing materials include (Et₂N)₄Hf, (Me₂N)₄Hf, (MeEtN)₄Hf, (^{t}BuC₅H₄)₂HfCl₂, (C₅H₅)₂HfCl₂, (EtC₅H₄)₂HfCl₂, (Me₅C₅)₂HfCl₂, (Me₅C₅)HfCl₃, (ⁱPrC₅H₄)₂HfCl₂, (ⁱPrC₅H₄)HfCl₃, (^{t}BuC₅H₄)₂HfMe₂, (acac)₄Hf, (hfac)₄Hf, (tfac)₄Hf, (thd)₄Hf, (NO₃)₄Hf, (^{t}BuO)₄Hf, (ⁱPrO)₄Hf, (EtO)₄Hf, (MeO)₄Hf or derivatives thereof. Preferably, hafnium precursors used during the deposition process herein include HfCl₄, (Et₂N)₄Hf or (Me₂N)₄Hf.

In an alternative embodiment, a variety of metal oxides or metal oxynitrides may be formed by sequentially pulsing metal precursors with oxidizing gas containing water vapor derived from a WVG system. The ALD processes disclosed herein may be altered by substituting the hafnium precursor with other metal precursors to form additional dielectric materials, such as hafnium aluminates, titanium aluminates, titanium oxynitrides, zirconium oxides, zirconium oxynitrides, zirconium aluminates, tantalum oxides, tantalum oxynitrides, titanium oxides, aluminum oxides, aluminum oxynitrides, lanthanum oxides, lanthanum oxynitrides, lanthanum aluminates, derivatives thereof or combinations thereof. In one embodiment, two or more ALD processes are concurrently conducted to deposit one layer on top of another. For example, a combined process contains a first ALD process to form a first dielectric material and a second ALD process to form a second dielectric material. The combined process may be used to produce a variety of hafnium-containing materials, for example, hafnium aluminum silicate or hafnium aluminum silicon oxynitride. In one example, a dielectric stack material is formed by depositing a first hafnium-containing material on a substrate and subsequently depositing a second hafnium-containing material thereon. The first and second hafnium-containing materials may vary in composition, so that one layer may contain hafnium oxide and the other layer may contain hafnium silicate. In one aspect, the lower layer contains silicon. Alternative metal precursors used during ALD processes described herein include ZrCl₄, Cp₂Zr, (Me₂N)₄Zr, (Et₂N)₄Zr, TaF₅, TaCl₅, (^{t}BuO)₅Ta, (Me₂N)₅Ta, (Et₂N)₅Ta, (Me₂N)₃Ta(N^{t}Bu), (Et₂N)₃Ta(N^{t}Bu), TiCl₄, TiI₄, (ⁱPrO)₄Ti, (Me₂N)₄Ti, (Et₂N)₄Ti, AlCl₃, Me₃Al, Me₂AlH, (AMD)₃La, ((Me₃Si)(^{t}Bu)N)₃La, ((Me₃Si)₂N)₃La, (^{t}Bu₂N)₃La, (ⁱPr₂N)₃La, derivatives thereof or combinations thereof.

The tantalum-containing precursor may be selected, for example, from the group of tantalum pentachloride (TaCl₅), pentakis(diethylamido) tantalum (PDEAT) (Ta(Net₂)₅), pentakis (ethylmethylamido) tantalum (PEMAT) (Ta(N(Et)(Me))₅), and pentakis(dimethylamido) tantalum (PDMAT) (Ta(Nme₂)₅), among others. The titanium-containing precursor may be selected, for example, from the group of titanium tetrachloride (TiCl₄), tetrakis(diethylamido) titanium (TDEAT) (Ti(Net₂)₄), tetrakis(ethylmethylamido) titanium (TEMAT) (Ti(N(Et)(Me))₄), and tetrakis(dimethylamido) titanium (TDMAT) (Ti(NMe₂)₄), among others.

Suitable rhodium precursors include, for example, the following rhodium compounds: 2,4-pentanedionatorhodium(I)dicarbonyl (C₅H₇Rh(CO)₂), tris(2,4-pentanedionato)rhodium i.e. rhodium(III)acetylacetonate (Rh(C₅H₇O₂)₃), and tris(trifluoro-2,4-pentanedionato)rhodium.

Suitable iridium precursors include, for example, the following iridium compounds: (methylcyclopentadienyl)(1,5-cyclooctadiene)iridium(I) ([(CH₃)C₅H₄](C₈H₁₂)Ir) and trisallyliridium ((C₃H₅)₃Ir).

Suitable palladium precursors include, for example, the following palladium compounds: Pd(thd)₂ and bis(1,1,1,5,5,5-hexafluoro-2,4-pentanedionato)palladium (Pd(CF₃COCHCOCF₃)₂).

Suitable platinum precursors include, for example, the following platinum compounds: platinum(II)hexafluoroacetylacetonate (Pt(CF₃COCHCOCF₃)₂), (trimethyl)methylcyclopentadienylplatinum(IV) ((CH₃)₃(CH₃C₅H₄)Pt), and allylcyclopentadienylplatinum ((C₃H₅)(C₅H₅)Pt).

Suitable low oxidation state osmium oxide precursors include, for example, the following osmium compounds: bis(cyclopentadienyl)osmium((C₅H₅)₂Os), bis(pentamethylcyclopentadienyl)osmium ([(CH₃)₅C₅]₂Os), and osmium(VIII)oxide (OsO₄).

Suitable vanadium precursors include, for example, VCl₄, VOCl, V(CO)₆ and VOCl₃.

In one example, a barrier material may be deposited on substrate 121 within process chamber 600 during a deposition process at step 1140. In one embodiment, substrate 121 may be exposed to a process gas containing a dielectric material precursor and an oxygen precursor during a CVD process. The precursors are generally provided from gas source 159 to inner chamber 101 through faceplate 152.

In one embodiment, the precursors may be introduced at step 140 into the process chamber or exposed to substrate 121 by inlet channel 156 simultaneously, such as during a traditional CVD process or sequentially, such as during an ALD process. The ALD process may expose the substrate to at least two deposition gases, such that, the substrate is sequentially exposed to a first precursor and a second precursor such as an oxygen precursor. Although one inlet channel 156 is shown, it is contemplated that the first precursor and the second precursor are provided to process chamber 600 in separate gas lines. The temperature may be controlled for each gas line.

A description of CVD and ALD processes and apparatuses that may be modified (e.g., incorporating a UV radiation source) and chemical precursors that may be useful for depositing dielectric materials are further disclosed in commonly assigned U.S. Pat. No. 6,858,547, issued Feb. 22, 2005, entitled SYSTEM AND METHOD FOR FORMING A GATE DIELECTRIC, U.S. Pat. No. 7,067,439, issued Sep. 19, 2002, entitled ALD METAL OXIDE DEPOSITION PROCESS USING DIRECT OXIDATION, U.S. Pat. No. 6,620,670, issued Sep. 16, 2003, entitled PROCESS CONDITIONS AND PRECURSORS FOR ATOMIC LAYER DEPOSITION (ALD) OF Al₂O₃, U.S. Pat. App. Pub. No. 2003-0232501, published Dec. 18, 2003, entitled SURFACE PRE-TREATMENT FOR ENHANCEMENT OF NUCLEATION OF HIGH DIELECTRIC CONSTANT MATERIALS, U.S. Pat. App. Pub. No. 2005-0271813, published Dec. 8, 2003, entitled APPARATUSES AND METHODS FOR ATOMIC LAYER DEPOSITION OF HAFNIUM-CONTAINING HIGH-K MATERIALS, U.S. Pat. App. Pub. No. 2006-0019033, published Jan. 26, 2006, entitled PLASMA TREATMENT OF HAFNIUM-CONTAINING MATERIALS, U.S. Pat. App. Pub. No. 2006-0062917, published Mar. 23, 2006, entitled VAPOR DEPOSITION OF HAFNIUM SILICATE MATERIALS WITH TRIS(DIMETHYLAMINO)SILANE which are all herein incorporated by reference in their entirety.

As the first precursor, for example, a hafnium precursor, and an oxygen precursor are combined in the process chamber, a hafnium-containing material, such as a hafnium oxide material, is formed on the substrate surface. The deposited hafnium oxide material exhibits good film qualities such as reflective index and wet etch rate. In one embodiment, the hafnium oxide material may be deposited at a rate within a range from about 10 Å/min to about 500 Å/min and is deposited to a thickness within a range from about 10 Å to about 1,000 Å. Hafnium oxide materials may have a chemical formula such as HfₓO_{y}, wherein an oxygen:hafnium atomic ratio (Y/X) is about 2 or less, for example, HfO₂. In one embodiment, the materials formed as described herein exhibits low hydrogen content and includes a small amount of carbon doping, which enhances boron retention in PMOS devices.

A carrier gas may be provided during step 1140 to control the partial pressure of the oxygen precursor and the hafnium precursor. The total internal pressure of a single wafer process chamber may be at a pressure within a range from about 100 mTorr to about 740 Torr, preferably, from about 250 mTorr to about 100 Torr, and more preferably, from about 500 mTorr to about 50 Torr. In one example, the internal pressure of the process chamber is maintained at a pressure of about 10 Torr or less, preferably, about 5 Torr or less, and more preferably, about 1 Torr or less. In some embodiments, the carrier gas may be provided to control the partial pressure of the oxygen precursor or the hafnium precursor within a range from about 100 mTorr to about 1 Torr for batch processing systems. Examples of suitable carrier gases include nitrogen, hydrogen, argon, helium, forming gas, or combinations thereof.

The substrate, the hafnium precursor, and/or the oxygen precursor may be exposed to an energy beam or a flux of energy generated by the photoexcitation system during the deposition process at step 1140. The use of the energy beam advantageously increases the deposition rate and improves surface diffusion or mobility of atoms within the hafnium oxide material to create active sites for incoming reactive species. In one embodiment, the beam has energy within a range from about 3.0 eV to about 9.84 eV. Also, the energy beam may have a wavelength within a range from about 123 nm to about 500 nm.

In one example, lamp 790 provides an energy beam to supply the excitation energy of at least one of the hafnium precursor or the oxygen precursor. The high deposition rate and the low deposition temperature produce a film having tunable properties with minimal parasitic side reactions. In one embodiment, the energy beam or flux may have a photon energy within a range from about 4.5 eV to about 9.84 eV. The substrate surface and the process gases may also be excited by lamp 790.

In another embodiment, the substrate containing the dielectric material (formed in step 1140) is exposed to a post-deposition treatment process during step 1150. The post-deposition treatment process increases the substrate surface energy after deposition, which advantageously removes volatiles and/or other film contaminants (such as by reducing the hydrogen content) and/or anneals the deposited film. A lower concentration of hydrogen from the deposited material advantageously increases tensile stress of the film. At least one lamp (e.g., lamp 790) may alternatively be utilized to energize an energy delivery gas which is exposed to the substrate to increase the surface energy of the substrate after deposition and to remove volatiles and/or other films.

Optionally, at step 1150, an energy delivery gas may be provided to inner chamber 101 of process chamber 600. Examples of suitable energy delivery gases include nitrogen, hydrogen, helium, argon, and combinations thereof. Examples provide that substrate 121 is treated with an energy beam or flux of energy during step 1150. In one example, lamp 792 provides an energy beam to supply the surface energy of substrate 121 during step 1150. In another example for annealing the barrier material, the energy beam or flux may have a photon energy within a range from about 3.53 eV to about 9.84 eV. Also, lamp 790 may produce an energy beam having a wavelength within a range from about 123 nm to about 500 nm. Generally, lamp 790 may be energized for a time period within a range from about 1 minute to about 10 minutes to facilitate post deposition treatment by photoexcitation.

In one example, volatile compounds or contaminants may be removed from the deposited film surface by exposing the substrate to an energy beam having a photon energy within a range from about 3.2 eV to about 4.5 eV is generated by lamp 790 is utilized to dissociate hafnium precursors and oxygen precursors within process chamber 600. Thus, excimer lamps, such as XeBr* (283 nm/4.41 eV), Br₂* (289 nm/4.29 eV), XeCl* (308 nm/4.03 eV), I₂* (342 nm/3.63 eV), XeF* (351 nm/3.53 eV) may be selected to remove hydrogen from the HfO₂ network. It is contemplated that the rotational speed of the substrate may be changed, for example, by increasing the rotation speed in step 1150 relative to the preceding deposition step.

In another embodiment, the substrate 121 may be removed from the process chamber 600 and the process chamber 600 is subsequently exposed to a chamber clean process during step 1160. The process chamber may be cleaned using a photoexcited cleaning agent. In one embodiment, the cleaning agent includes fluorine.

Process chamber 600 may be cleaned during a chamber clean process to enhance deposition performance. For example, the chamber clean process may be used to remove contaminants contained on the surfaces of process chamber 600 or contaminants contained on windows 793, thereby minimizing transmission losses of the energy beam or flux traveling through window 793 and maximizing the energy transferred to the gases and surfaces. Window 793 may be cleaned with greater frequency than process chamber 600, for example, process chamber 600 may be cleaned after processing a number of substrates while window 793 is cleaned after processing each substrate. Suitable cleaning agents include, for example, H₂, HX (where X═F, Cl, Br, or I), NX₃ (where X═F or Cl), interhalogen compounds such as XFₙ (where X═Cl, Br, I and n=1, 3, 5, 7) and its hydrogenated inter-halogen compounds, and inert gas halides such as XeF₂, XeF₄, XeF₆, and KrF₂.

The elemental composition of the dielectric material deposited during step 1140 may be predetermined by controlling the concentration or flow rate of the chemical precursors, namely the first precursor and oxygen precursor. Film properties may be tailored for specific applications by controlling the relative concentrations of the dielectric precursor and oxygen precursor within the dielectric material. In one embodiment, the elemental concentrations of the dielectric precursor and oxygen precursor may be tuned by varying the range of the UV energy during or subsequent to the deposition process. The film properties include wet etch rate, dry etch rate, stress, dielectric constant, and the like. For example, by reducing the hydrogen content, the deposited material may have a higher tensile stress. In another example, by reducing the carbon content, the deposited material may have a lower electrical resistance.

Dielectric materials deposited utilizing process 1100 as described herein may be used throughout electronic features/devices due to several physical properties. In one embodiment, dielectric materials may be deposited during process 1100 as layers on a substrate to form electronic features, such as an integrated circuit (FIG. 14).

### Conductive Materials

FIG. 12 depicts a flow diagram of process 1200 for depositing a conductive material, as described by embodiments herein. The substrate may be positioned within a process chamber (step 1210), optionally exposed to a pretreatment process (step 1220), and heated to a predetermined temperature (step 1230). Subsequently, a conductive material may be deposited on the substrate (step 1240). The substrate may be optionally exposed to a post-deposition treatment process (step 1250) and the process chamber may be optionally exposed to a chamber clean process (step 1260).

The substrate may be positioned within a process chamber during step 1210. The process chamber may be a single wafer chamber or a batch chamber containing multiple wafers or substrates (e.g., 25, 50, 100, or more). The substrate may be maintained in a fixed position, but preferably, is rotated by a support pedestal. Optionally, the substrate may be indexed during one or more steps of process 1200.

Process chamber 600, depicted in FIG. 7, may be used during process 1200 to deposit conductive materials on substrate 121 as described by examples herein. In one example, substrate 121 may be rotated on a substrate support pedestal within process chamber 600 at a rate of up to about 120 rpm (revolutions per minute). Alternatively, substrate 121 may be positioned on substrate support pedestal and not rotated during the deposition process.

In one embodiment, the substrate 121 is optionally exposed to at least one pretreatment process during step 1220. The substrate surface may contain native oxides that are removed during a pretreatment process. The substrate 121 may be pretreated with an energy beam generated by a direct photoexcitation system to remove the native oxides from the substrate surface prior to depositing a conductive material during step 1240. A process gas may be exposed to the substrate during the pretreatment process. The process gas may contain argon, nitrogen, helium, hydrogen, forming gas, or combinations thereof. The pretreatment process may last for a time period within a range from about 2 minutes to about 10 minutes to facilitate native oxide removal during a photoexcitation process. Also, the substrate 121 may be heated during step 1220 to a temperature within a range from about 100° C. to about 800° C., preferably, from about 200° C. to about 600° C., and more preferably, from about 300° C. to about 500° C., to facilitate native oxide removal during process 1200.

Examples provide that substrate 121 may be exposed to an energy beam produced by lamp 792 during step 1220. Lamp 792 may provide an energy beam having a photon energy within a range from about 2 eV to about 10 eV, for example from about 3.0 eV to about 9.84 eV. In another example, lamp 792 provides an energy beam of UV radiation having a wavelength within a range from about 123 nm to about 500 nm. Lamp 792 may be energized for a period sufficient to remove oxides. The energization period is selected based upon the size and geometry of window 793 and the substrate rotation speed. In one embodiment, lamp 792 is energized for a time period within a range from about 2 minutes to about 10 minutes to facilitate native oxide removal during a photoexcitation process. In one example, substrate 121 may be heated to a temperature within a range from about 100° C. to about 800° C. during step 1220. In another example, substrate 121 may be heated to a temperature within a range from about 300° C. to about 500° C. during step 1220, while lamp 792 provides an energy beam having a photon energy within a range from about 2 eV to about 10 eV for a time period within a range from about 2 minutes to about 5 minutes to facilitate native oxide removal. In one example, the energy beam has a photon energy within a range from about 3.2 eV to about 4.5 eV for about 3 minutes.

In another embodiment, native oxide removal may be augmented by a photoexcitation process in the presence of a process gas containing an energy delivery gas during a pretreatment process at step 1220. The energy delivery gas may be neon, argon, krypton, xenon, argon bromide, argon chloride, krypton bromide, krypton chloride, krypton fluoride, xenon fluorides (e.g., XeF₂), xenon chlorides, xenon bromides, fluorine, chlorine, bromine, excimers thereof, radicals thereof, derivatives thereof, or combinations thereof. In some embodiments, the process gas may also contain nitrogen gas (N₂), hydrogen gas (H₂), forming gas (e.g., N₂/H₂ or Ar/H₂) besides at least one energy delivery gas.

In one example, substrate 121 may be exposed to a process gas containing an energy delivery gas by providing the process gas to inner chamber 101 of process chamber 600 during step 1220. The energy delivery gas may be provided through faceplate 152 from gas source 159. The proximity of the process gas to lamp 792 compared to substrate 121 readily excites the energy delivery gas therein. As the energy delivery gas de-excites and moves closer to substrate 121, the energy is efficiently transferred to the surface of substrate 121, thereby facilitating the removal of native oxides.

In another embodiment, native oxide removal may be augmented by a photoexcitation process in the presence of a process gas containing an organic vapor during the pretreatment process at step 1220. In one example, the substrate may be exposed to the process gas containing a cyclic aromatic hydrocarbon. The cyclic aromatic hydrocarbon may be in the presence of UV radiation. Monocyclic aromatic hydrocarbons and polycyclic aromatic hydrocarbons that are useful during a pretreatment process include quinone, hydroxyquinone (hydroquinone), anthracene, naphthalene, phenanthracene, derivatives thereof, or combinations thereof. In another example, the substrate may be exposed to the process gas containing other hydrocarbons, such as unsaturated hydrocarbons, including ethylene, acetylene (ethyne), propylene, alkyl derivatives, halogenated derivates, or combinations thereof. In another example, the organic vapor may contain alkane compounds during the pretreatment process at step 1220.

In one example, the UV radiation having a wavelength within a range from about 123 nm to about 500 nm may be generated by a lamp during step 1120. In another embodiment, polycyclic aromatic hydrocarbons may remove native oxides in the presence of UV radiation by reacting with oxygen atoms within the native oxides. In another embodiment, native oxides may be removed by exposing the substrate to quinone or hydroxyquinone while forming derivative products. The derivative product may be removed from the process chamber by a vacuum pumping process.

At step 1230, the substrate 121 may be heated to a predetermined temperature during or subsequent to the pretreatment process. The substrate 121 is heated prior to depositing the dielectric material at step 1240. The substrate may be heated by an embedded heating element within the substrate support, the energy beam (e.g., UV-source), or combinations thereof. Generally, the substrate is heated long enough to obtain the predetermined temperature, such as for a time period within a range from about 15 seconds to about 30 minutes, preferably, from about 30 seconds to about 20 minutes, and more preferably, from about 1 minute to about 10 minutes. In one embodiment, the substrate may be heated to a temperature within a range from about 200° C. to about 1,000° C., preferably, from about 400° C. to about 850° C., and more preferably, from about 550° C. to about 800° C. In another embodiment, the substrate may be heated to a temperature of less than about 550° C., preferably, less than about 450° C.

In one example, substrate 121 may be heated to the predetermined temperature within process chamber 600. The predetermined temperature may be within a range from about 300° C. to about 500° C. Substrate 121 may be heated by applying power from a power source to a heating element, for example heater block 211.

In one embodiment, a conductive material is deposited on the substrate during a deposition process at step 1240. The conductive material may be formed by exposing the substrate to at least one deposition gas during the deposition process. In one example, the deposition process is a CVD process having a deposition gas that may contain a metal precursor, for example, tungsten, titanium, or combinations thereof, and a nitrogen precursor or a precursor containing both the metal precursor and nitrogen source. Alternatively, the deposition process may be an ALD process having at least two deposition gases, such that, the substrate is sequentially exposed to a metal precursor and a nitrogen precursor. The deposition process may be a thermal process, a radical process, or a combination thereof. For example, the substrate may be exposed to a process gas in the presence of an energy beam by a direct photoexcitiation system.

In one embodiment, the conductive material contains nitrogen and at least one metal, such as tungsten, titanium, or combinations thereof. The conductive material may have a composition that includes tungsten-containing materials, such as tungsten nitride (WN), titanium containing materials, such as titanium nitride (TiN), derivatives thereof or combinations thereof. Other conductive materials may include tungsten and aluminum, among others.

Examples of suitable nitrogen precursors for forming conductive materials at step 140 include ammonia (NH₃), hydrazine (N₂H₄), organic amines, organic hydrazines, organic diazines (e.g., methyldiazine ((H₃C)NNH)), silylazides, silylhydrazines, hydrogen azide (HN₃), hydrogen cyanide (HCN), atomic nitrogen (N), nitrogen (N₂), derivatives thereof, or combinations thereof. Organic amines as nitrogen precursors include RₓNH₃₋ₓ, where each R is independently an alkyl group or an aryl group and x is 1, 2, or 3. Examples of organic amines include trimethylamine ((CH₃)₃N), dimethylamine ((CH₃)₂NH), methylamine ((CH₃)NH₂)), triethylamine ((CH₃CH₂)₃N), diethylamine ((CH₃CH₂)₂NH), ethylamine ((CH₃CH₂)NH₂)), tertbutylamine (((CH₃)₃C)NH₂), derivatives thereof, or combinations thereof. Organic hydrazines as nitrogen precursors include RₓN₂H₄₋ₓ, where each R is independently an alkyl group or an aryl group and x is 1, 2, 3, or 4. Examples of organic hydrazines include methylhydrazine ((CH₃)N₂H₃), dimethylhydrazine ((CH₃)₂N₂H₂), ethylhydrazine ((CH₃CH₂)N₂H₃), diethylhydrazine ((CH₃CH₂)₂N₂H₂), tertbutylhydrazine (((CH₃)₃C)N₂H₃), ditertbutylhydrazine (((CH₃)₃C)₂N₂H₂), radicals thereof, plasmas thereof, derivatives thereof, or combinations thereof.

Exemplary tungsten precursors are selected from tungsten hexafluoride (WF₆) and tungsten carbonyl (W(CO)₆). The titanium-containing precursor may be selected, for example, from the group of titanium tetrachloride (TiCl₄), tetrakis(diethylamido) titanium (TDEAT) (Ti(Net₂)₄), tetrakis(ethylmethylamido) titanium (TEMAT) (Ti(N(Et)(Me))₄), and tetrakis(dimethylamido) titanium (TDMAT) (Ti(NMe₂)₄), among others.

Suitable reducing gases may include traditional reductants, for example, hydrogen (e.g., H₂ or atomic-H), ammonia (NH₃), silane (SiH₄), disilane (Si₂H₆), trisilane (Si₃H₈), tetrasilane (Si₄H₁₀), dimethylsilane (SiC₂H₈), methyl silane (SiCH₆), ethylsilane (SiC₂H₈), chlorosilane (ClSiH₃), dichlorosilane (Cl₂SiH₂), hexachlorodisilane (Si₂Cl₆), borane (BH₃), diborane (B₂H₆), triborane, tetraborane, pentaborane, alkylboranes, such as triethylborane (Et₃B), derivatives thereof and combinations thereof.

In one example, a conductive material may be deposited on substrate 121 within process chamber 600 during a deposition process at step 1240. In one embodiment, substrate 121 may be exposed to a process gas containing a conductive material precursor, such as a tungsten precursor or a titanium-containing precursor and a nitrogen precursor during a CVD process. The precursors are generally provided from gas source 159 to inner chamber 101 through faceplate 152.

In one embodiment, the precursors may be introduced at step 1240 into process chamber or exposed to substrate 121 by inlet channel 156 simultaneously, such as during a traditional CVD process or sequentially, such as during an ALD process. The ALD process may expose the substrate to at least two deposition gases, such that, the substrate is sequentially exposed to a first precursor such as a tungsten containing precursor or a titanium-containing precursor, and a second precursor such a nitrogen containing precursor. Although one inlet channel 156 is shown, it is contemplated that the first precursor and the second precursor are provided to process chamber 600 in separate gas lines. The temperature may be controlled for each gas line.

A description of CVD and ALD processes and apparatuses that may be modified (e.g., incorporating a UV radiation source) and chemical precursors that may be useful for depositing conductive materials are further disclosed in commonly assigned U.S. Pat. No. 6,811,814, issued Nov. 2, 2004, entitled METHOD FOR GROWING THIN FILMS BY CATALYTIC ENHANCEMENT, U.S. Pat. No. 6,620,956, issued Sep. 16, 2003, entitled NITROGEN ANALOGS OF COPPER II B-DIKETONATES AS SOURCE REAGENTS FOR SEMICONDUCTOR PROCESSING, U.S. Pat. No. 6,740,585, issued May 25, 2004, entitled BARRIER FORMATION USING NOVEL SPUTTER DEPOSITION METHOD WITH PVD, CVD, OR ALD, U.S. Pat. App. Pub. No. 2004-0009665, published Jan. 15, 2004, entitled DEPOSITION OF COPPER FILMS, U.S. Pat. App. Pub. No. 2005-0220998, published Oct. 6, 2005, entitled NOBLE METAL LAYER FORMATION FOR COPPER FILM DEPOSITION, U.S. Pat. App. Pub. No. 2004-0105934, published Jun. 3, 2004, entitled RUTHENIUM LAYER FORMATION FOR COPPER FILM DEPOSITION, U.S. Pat. App. Pub. No. 2004-0241321, published Dec. 12, 2004, entitled RUTHENIUM LAYER FORMATION FOR COPPER FILM DEPOSITION, which are all herein incorporated by reference in their entirety.

As the first precursor, for example, a tungsten precursor, and a nitrogen precursor are combined in the process chamber, a tungsten-containing material, such as a tungsten nitride material, is formed on the substrate surface. The deposited tungsten nitride material exhibits good film qualities such as reflective index and wet etch rate. In one embodiment, the tungsten nitride material may be deposited at a rate within a range from about 10 Å/min to about 500 Å/min and is deposited to a thickness within a range from about 10 Å to about 1,000 Å.

A carrier gas may be provided during step 1240 to control the partial pressure of the tungsten precursor and the nitrogen precursor. The total internal pressure of a single wafer process chamber may be at a pressure within a range from about 100 mTorr to about 740 Torr, preferably, from about 250 mTorr to about 100 Torr, and more preferably, from about 500 mTorr to about 50 Torr. In one example, the internal pressure of the process chamber is maintained at a pressure of about 10 Torr or less, preferably, about 5 Torr or less, and more preferably, about 1 Torr or less. In some embodiments, the carrier gas may be provided to control the partial pressure of the nitrogen precursor or the tungsten mobility of atoms within the ruthenium material to create active sites for incoming reactive species. In one embodiment, the beam has energy within a range from about 3.0 eV to about 9.84 eV. Also, the energy beam may have a wavelength within a range from about 126 nm to about 450 nm.

In one example, lamp 790 provides an energy beam to supply the excitation energy of at least one of the precursors. The high deposition rate and the low deposition temperature produce a seed layer having tunable properties with minimal parasitic side reactions. In one embodiment, the energy beam or flux may have a photon energy within a range from about 4.5 eV to about 9.84 eV. The substrate surface and the process gases may also be excited by lamp 790.

In another embodiment, the substrate containing the seed layer (formed in step 1240) is exposed to a post-deposition treatment process during step 1350. The post-deposition treatment process increases the substrate surface energy after deposition, which advantageously removes volatiles and/or other film contaminants (such as by reducing the hydrogen content) and/or anneals the deposited film. A lower concentration of hydrogen from the deposited material advantageously increases tensile stress of the film. At least one lamp (e.g., lamp 790) may alternatively be utilized to energize an energy delivery gas which is exposed to the substrate to increase the surface energy of the substrate after deposition and to remove volatiles and/or other films.

Optionally, at step 1350, an energy delivery gas may be provided to inner chamber 101 of process chamber 600. Examples of suitable energy delivery gases include nitrogen, hydrogen, helium, argon, and combinations thereof. Examples provide that substrate 121 is treated with an energy beam or flux of energy during step 1350. In one example, lamp 792 provides an energy beam to supply the surface energy of substrate 121 during step 1350. In another example for annealing the barrier material, the energy beam or flux may have a photon energy within a range from about 3.53 eV to about 9.84 eV. Also, lamp 790 may produce an energy beam having a wavelength within a range from about 126 nm to about 351 nm. Generally, lamp 790 may be energized for a time period precursor within a range from about 100 mTorr to about 1 Torr for batch processing systems. Examples of suitable carrier gases include nitrogen, hydrogen, argon, helium, forming gas, or combinations thereof.

The substrate, the tungsten precursor, and/or the nitrogen precursor may be exposed to an energy beam or a flux of energy generated by the photoexcitation system during the deposition process at step 1240. The use of the energy beam advantageously increases the deposition rate and improves surface diffusion or mobility of atoms within the tungsten nitride material to create active sites for incoming reactive species. In one embodiment, the beam has energy within a range from about 3.0 eV to about 9.84 eV. Also, the energy beam may have a wavelength within a range from about 126 nm to about 450 nm.

In one example, lamp 790 provides an energy beam to supply the excitation energy of at least one of the tungsten precursors or the nitrogen precursor. The high deposition rate and the low deposition temperature produce a film having tunable properties with minimal parasitic side reactions. In one embodiment, the energy beam or flux may have a photon energy within a range from about 4.5 eV to about 9.84 eV. The substrate surface and the process gases may also be excited by lamp 790.

In another embodiment, the substrate containing the conductive material (formed in step 1240) is exposed to a post-deposition treatment process during step 1250. The post-deposition treatment process increases the substrate surface energy after deposition, which advantageously removes volatiles and/or other film contaminants (such as by reducing the hydrogen content) and/or anneals the deposited film. A lower concentration of hydrogen from the deposited material advantageously increases tensile stress of the film. At least one lamp (e.g., lamp 790) may alternatively be utilized to energize an energy delivery gas which is exposed to the substrate to increase the surface energy of the substrate after deposition and to remove volatiles and/or other films.

Optionally, at step 1250, an energy delivery gas may be provided to inner chamber 101 of process chamber 600. Examples of suitable energy delivery gases include nitrogen, hydrogen, helium, argon, and combinations thereof. Examples provide that substrate 121 is treated with an energy beam or flux of energy during step 1250. In one example, lamp 792 provides an energy beam to supply the surface energy of substrate 121 during step 1250. In another example for annealing the conductive material, the energy beam or flux may have a photon energy within a range from about 3.53 eV to about 9.84 eV. Also, lamp 790 may produce an energy beam having a wavelength within a range from about 126 nm to about 351 nm. Generally, lamp 790 may be energized for a time period within a range from about 1 minute to about 10 minutes to facilitate post deposition treatment by photoexcitation.

In one example, volatile compounds or contaminants may be removed from the deposited film surface by exposing the substrate to an energy beam having a photon energy within a range from about 3.2 eV to about 4.5 eV is generated by lamp 790 is utilized to dissociate tungsten or titanium precursors and nitrogen precursors within process chamber 600. Thus, excimer lamps, such as XeBr* (283 nm/4.41 eV), Br₂* (289 nm/4.29 eV), XeCl* (308 nm/4.03 eV), I₂* (342 nm/3.63 eV), XeF* (351 nm/3.53 eV) may be selected to remove hydrogen from the TiN or WN network. It is contemplated that the rotational speed of the substrate may be changed, for example, by increasing the rotation speed in step 1250 relative to the preceding deposition step.

In another embodiment, the substrate 121 may be removed from the process chamber 600 and the process chamber 600 is subsequently exposed to a chamber clean process during step 1260. The process chamber may be cleaned using a photoexcited cleaning agent. In one embodiment, the cleaning agent includes fluorine.

Process chamber 600 may be cleaned during a chamber clean process to enhance deposition performance. For example, the chamber clean process may be used to remove contaminants contained on the surfaces of process chamber 600 or contaminants contained on windows 793, thereby minimizing transmission losses of the energy beam or flux traveling through window 793 and maximizing the energy transferred to the gases and surfaces. Window 793 may be cleaned with greater frequency than process chamber 600, for example, process chamber 600 may be cleaned after processing a number of substrates while window 793 is cleaned after processing each substrate. Suitable cleaning agents include, for example, H₂, HX (where X═F, Cl, Br, or I), NX₃ (where X═F or Cl), interhalogen compounds such as XFₙ (where X═Cl, Br, I and n=1, 3, 5, 7) and its hydrogenated inter-halogen compounds, and inert gas halides such as XeF₂, XeF₄, XeF₆, and KrF₂.

The elemental composition of the conductive material deposited during step 1240 may be predetermined by controlling the concentration or flow rate of the chemical precursors, namely the metal precursor and nitrogen precursor. Film properties may be tailored for specific applications by controlling the relative concentrations of metal precursors and nitrogen precursors within the conductive material. In one embodiment, the elemental concentrations of the metal precursors may be tuned by varying the range of the UV energy during or subsequent to the deposition process. The film properties include wet etch rate, dry etch rate, stress, dielectric constant, and the like.

Conductive materials deposited utilizing process 1200 as described herein may be used throughout electronic features/devices due to several physical properties. In one embodiment, conductive materials may be deposited during process 1200 as layers on a substrate to form electronic features, such as an integrated circuit (FIG. 14).

Apparatuses and processes that may be used to form the conductive layers and materials are further described in commonly assigned U.S. Ser. No. 10/443,648, filed May 22, 2003, and published as US 2005-0220998, U.S. Ser. No. 10/634,662, filed Aug. 4, 2003, and published as US 2004-0105934, U.S. Ser. No. 10/811,230, filed Mar. 26, 2004, and published as US 2004-0241321, U.S. Ser. No. 60/714,580, filed Sep. 6, 2005, and in commonly assigned U.S. Pat. Nos. 6,936,538, 6,620,723, 6,551,929, 6,855,368, 6,797,340, 6,951,804,6,939,801, 6,972,267, 6,596,643, 6,849,545, 6,607,976, 6,702,027, 6,916,398, 6,878,206, and 6,936,906, which are herein incorporated by reference in their entirety.

### Seed Materials

FIG. 12 depicts a flow diagram of process 1300 for depositing a seed material, as described by embodiments herein. The substrate may be positioned within a process chamber (step 1310), optionally exposed to a pretreatment process (step 1320), and heated to a predetermined temperature (step 1330). Subsequently, a seed material may be deposited on the substrate (step 1340). The substrate may be optionally exposed to a post-deposition treatment process (step 1350) and the process chamber may be optionally exposed to a chamber clean process (step 1360).

The substrate may be positioned within a process chamber during step 1310. The process chamber may be a single wafer chamber or a batch chamber containing multiple wafers or substrates (e.g., 25, 50, 100, or more). The substrate may be maintained in a fixed position, but preferably, is rotated by a support pedestal. Optionally, the substrate may be indexed during one or more steps of process 1300.

Process chamber 600, depicted in FIG. 7, may be used during process 1300 to deposit seed materials on substrate 121 as described by examples herein. In one example, substrate 121 may be rotated on a substrate support pedestal within process chamber 600 at a rate of up to about 120 rpm (revolutions per minute). Alternatively, substrate 121 may be positioned on substrate support pedestal and not rotated during the deposition process.

In one embodiment, the substrate 121 is optionally exposed to at least one pretreatment process during step 1320. The substrate surface may contain native oxides that are removed during a pretreatment process. The substrate 121 may be pretreated with an energy beam generated by direct photoexcitation system to remove the native oxides from the substrate surface prior to depositing a seed material during step 1340. A process gas may be exposed to the substrate during the pretreatment process. The process gas may contain argon, nitrogen, helium, hydrogen, forming gas, or combinations thereof. The pretreatment process may last for a time period within a range from about 2 minutes to about 10 minutes to facilitate native oxide removal during a photoexcitation process. Also, the substrate 121 may be heated during step 1320 to a temperature within a range from about 100° C. to about 800° C., preferably, from about 200° C. to about 600° C., and more preferably, from about 300° C. to about 500° C., to facilitate native oxide removal during process 1300.

Examples provide that substrate 121 may be exposed to an energy beam produced by lamp 792 during step 1320. Lamp 792 may provide an energy beam having a photon energy within a range from about 2 eV to about 10 eV, for example from about 3.0 eV to about 9.84 eV. In another example, lamp 792 provides an energy beam of UV radiation having a wavelength within a range from about 123 nm to about 500 nm. Lamp 792 may be energized for a period sufficient to remove oxides. In one embodiment, lamp 792 is energized for a time period within a range from about 2 minutes to about 10 minutes to facilitate native oxide removal during a photoexcitation process. In one example, substrate 121 may be heated to a temperature within a range from about 100° C. to about 800° C. during step 1320. In another example, substrate 121 may be heated to a temperature within a range from about 300° C. to about 500° C. during step 1320, while lamp 792 provides an energy beam having a photon energy within a range from about 2 eV to about 10 eV for a time period within a range from about 2 minutes to about 5 minutes to facilitate native oxide removal. In one example, the energy beam has a photon energy within a range from about 3.2 eV to about 4.5 eV for about 3 minutes.

In another embodiment, native oxide removal may be augmented by a photoexcitation process in the presence of a process gas containing an energy delivery gas during a pretreatment process at step 1320. The energy delivery gas may be neon, argon, krypton, xenon, argon bromide, argon chloride, krypton bromide, krypton chloride, krypton fluoride, xenon fluorides (e.g., XeF₂), xenon chlorides, xenon bromides, fluorine, chlorine, bromine, excimers thereof, radicals thereof, derivatives thereof, or combinations thereof. In some embodiments, the process gas may also contain nitrogen gas (N₂), hydrogen gas (H₂), forming gas (e.g., N₂/H₂ or Ar/H₂) besides at least one energy delivery gas.

In one example, substrate 121 may be exposed to a process gas containing an energy delivery gas by providing the process gas to inner chamber 101 of process chamber 600 during step 1320. The energy delivery gas may be provided through faceplate 152 from gas source 159. The proximity of the process gas to lamp 792 compared to substrate 121 readily excites the energy delivery gas therein. As the energy delivery gas de-excites and moves closer to substrate 121, the energy is efficiently transferred to the surface of substrate 121, thereby facilitating the removal of native oxides.

In another embodiment, native oxide removal may be augmented by a photoexcitation process in the presence of a process gas containing an organic vapor during the pretreatment process at step 1320. In one example, the substrate may be exposed to the process gas containing a cyclic aromatic hydrocarbon. The cyclic aromatic hydrocarbon may be in the presence of UV radiation. Monocyclic aromatic hydrocarbons and polycyclic aromatic hydrocarbons that are useful during a pretreatment process include quinone, hydroxyquinone (hydroquinone), anthracene, naphthalene, phenanthracene, derivatives thereof, or combinations thereof. In another example, the substrate may be exposed to the process gas containing other hydrocarbons, such as unsaturated hydrocarbons, including ethylene, acetylene (ethyne), propylene, alkyl derivatives, halogenated derivates, or combinations thereof. In another example, the organic vapor may contain alkane compounds during the pretreatment process at step 1320.

In one example, the UV radiation having a wavelength within a range from about 126 nm to about 351 nm may be generated by a lamp during step 1320. In another embodiment, polycyclic aromatic hydrocarbons may remove native oxides in the presence of UV radiation by reacting with oxygen atoms within the native oxides. In another embodiment, native oxides may be removed by exposing the substrate to quinone or hydroxyquinone while forming derivative products. The derivative product may be removed from the process chamber by a vacuum pumping process.

At step 1330, the substrate 121 may be heated to a predetermined temperature during or subsequent to the pretreatment process. The substrate 121 is heated prior to depositing the dielectric material at step 1240. The substrate may be heated by an embedded heating element within the substrate support, the energy beam (e.g., UV-source), or combinations thereof. Generally, the substrate is heated long enough to obtain the predetermined temperature, such as for a time period within a range from about 15 seconds to about 30 minutes, preferably, from about 30 seconds to about 20 minutes, and more preferably, from about 1 minute to about 10 minutes. In one embodiment, the substrate may be heated to a temperature within a range from about 200° C. to about 1,000° C., preferably, from about 400° C. to about 850° C., and more preferably, from about 550° C. to about 800° C. In another embodiment, the substrate may be heated to a temperature of less than about 550° C., preferably, less than about 450° C.

In one example, substrate 121 may be heated to the predetermined temperature within process chamber 600. The predetermined temperature may be within a range from about 300° C. to about 500° C. Substrate 121 may be heated by applying power from a power source to a heating element, for example heater block 211.

In one embodiment, a seed material is deposited on the substrate during a deposition process at step 1340. The seed material may be formed by exposing the substrate to at least one deposition gas during the deposition process. In one example, the deposition process is a CVD process having a deposition gas that may contain a first precursor and a second precursor or a precursor containing both the first and second precursor. Alternatively, the deposition process may be an ALD process having at least two deposition gases, such that, the substrate is sequentially exposed to a first precursor and a second precursor. The deposition process may be a thermal process, a radical process, or a combination thereof. For example, the substrate may be exposed to a process gas in the presence of an energy beam by a direct photoexcitiation system.

The seed material contains at least one metal, such as ruthenium, iridium, tungsten, tantalum, platinum, copper, or combinations thereof. The seed material may also have a composition that includes tantalum-containing materials, such as tantalum nitride (TaN).

Examples of suitable ruthenium containing precursors for forming seed layers at step 1340 may include ruthenocene compounds and ruthenium compounds containing at least one open chain dienyl ligand. Ruthenocene compounds contain at least one cyclopentyl ligand such as RₓC₅H₅₋ₓ, where x=0-5 and R is independently hydrogen or an alkyl group and include bis(cyclopentadienyl)ruthenium compounds, bis(alkylcyclopentadienyl)ruthenium compounds, bis(dialkylcyclopentadienyl)ruthenium compounds and derivatives thereof, where the alkyl groups may be independently methyl, ethyl, propyl or butyl. A bis(cyclopentadienyl)ruthenium compound has a generic chemical formula (RₓC₅H₅₋ₓ)₂Ru, where x=0-5 and R is independently hydrogen or an alkyl group such as methyl, ethyl, propyl or butyl.

Ruthenium compounds containing at least one open chain dienyl ligand may contain a ligand such as CH₂CRCHCRCH₂, where R is independently an alkyl group or hydrogen. In some examples, the ruthenium-containing precursor may have two open-chain dienyl ligands, such as pentadienyl or heptadienyl and include bis(pentadienyl)ruthenium compounds, bis(alkylpentadienyl)ruthenium compounds and bis(dialkylpentadienyl)ruthenium compounds. A bis(pentadienyl)ruthenium compound has a generic chemical formula (CH₂CRCHCRCH₂)₂Ru, where R is independently an alkyl group or hydrogen. Usually, R is independently hydrogen, methyl, ethyl, propyl or butyl. Also, ruthenium-containing precursor may have both an one open-chain dienyl ligand and a cyclopentadienyl ligand.

Therefore, examples of ruthenium-containing precursors useful during the deposition process described herein include bis(cyclopentadienyl)ruthenium (Cp₂Ru), bis(methylcyclopentadienyl)ruthenium, bis(ethylcyclopentadienyl)ruthenium, bis(pentamethylcyclopentadienyl)ruthenium, bis(2,4-dimethylpentadienyl)ruthenium, bis(2,4-diethylpentadienyl)ruthenium, bis(2,4-diisopropylpentadienyl)ruthenium, bis(2,4-ditertbutylpentadienyl)ruthenium, bis(methylpentadienyl)ruthenium, bis(ethylpentadienyl)ruthenium, bis(isopropylpentadienyl)ruthenium, bis(tertbutylpentadienyl)ruthenium, derivatives thereof and combinations thereof. In some embodiments, other ruthenium-containing compounds include tris(2,2,6,6-tetramethyl-3,5-heptanedionato)ruthenium, dicarbonyl pentadienyl ruthenium, ruthenium acetyl acetonate, (2,4-dimethylpentadienyl)ruthenium(cyclopentadienyl), bis(2,2,6,6-tetramethyl-3,5-heptanedionato)ruthenium(1,5-cyclooctadiene), (2,4-dimethylpentadienyl)ruthenium(methylcyclopentadienyl), (1,5-cyclooctadiene)ruthenium(cyclopentadienyl), (1,5-cyclooctadiene)ruthenium(methylcyclopentadienyl), (1,5-cyclooctadiene)ruthenium(ethylcyclopentadienyl), (2,4-dimethylpentadienyl)ruthenium(ethylcyclopentadienyl), (2,4-dimethylpentadienyl)ruthenium(isopropylcyclopentadienyl), bis(N,N-dimethyl 1,3-tetramethyl diiminato)ruthenium(1,5-cyclooctadiene), bis(N,N-dimethyl 1,3-dimethyl diiminato)ruthenium(1,5-cyclooctadiene), bis(allyl)ruthenium(1,5-cyclooctadiene), (η⁶-C₆H₆)ruthenium(1,3-cyclohexadiene), bis(1,1-dimethyl-2-aminoethoxylato)ruthenium(1,5-cyclooctadiene), bis(1,1-dimethyl-2-aminoethylaminato)ruthenium(1,5-cyclooctadiene), derivatives thereof and combinations thereof.

Other noble metal-containing compounds may be used as a substitute for ruthenium-containing precursors to deposit their respective noble metal layer, such as precursors containing palladium, platinum, cobalt, nickel and rhodium. Palladium-containing precursors, for example, bis(allyl)palladium, bis(2-methylallyl)palladium, and (cyclopentadienyl)(allyl)palladium, derivatives thereof and combinations thereof. Suitable platinum-containing precursors include dimethyl(cyclooctadiene)platinum, trimethyl(cyclopentadienyl)platinum, trimethyl(methylcyclopentadienyl)platinum, cyclopentadienyl(allyl)platinum, methyl(carbonyl)cyclopentadienylplatinum, trimethyl(acetylacetonato)platinum, bis(acetylacetonato)platinum, derivatives thereof and combinations thereof. Suitable cobalt-containing precursors include bis(cyclopentadienyl)cobalt, (cyclopentadienyl)(cyclohexadienyl)cobalt, cyclopentadienyl(1,3-hexadienyl)cobalt, (cyclobutadienyl)(cyclopentadienyl)cobalt, bis(methylcyclopentadienyl)cobalt, (cyclopentadienyl)(5-methylcyclopentadienyl)cobalt, bis(ethylene) (pentamethylcyclopentadienyl)cobalt, derivatives thereof and combinations thereof. A suitable nickel-containing precursor includes bis(methylcyclopentadienyl) nickel and suitable rhodium-containing precursors include bis(carbonyl)(cyclopentadienyl)rhodium, bis(carbonyl)(ethylcyclopentadienyl)rhodium, bis(carbonyl)(methylcyclopentadienyl)rhodium, bis(propylene)rhodium, derivatives thereof and combinations thereof.

Suitable reducing gases may include traditional reductants, for example, hydrogen (e.g., H₂ or atomic-H), ammonia (NH₃), silane (SiH₄), disilane (Si₂H₆), trisilane (Si₃H₈), tetrasilane (Si₄H₁₀), dimethylsilane (SiC₂H₈), methyl silane (SiCH₆), ethylsilane (SiC₂H₈), chlorosilane (ClSiH₃), dichlorosilane (Cl₂SiH₂), hexachlorodisilane (Si₂Cl₆), borane (BH₃), diborane (B₂H₆), triborane, tetraborane, pentaborane, alkylboranes, such as triethylborane (Et₃B), derivatives thereof and combinations thereof.

Also, the reducing gas may include oxygen-containing gases used as a reductant, such as oxygen (e.g., O₂), nitrous oxide (N₂O), nitric oxide (NO), nitrogen dioxide (NO₂), derivatives thereof and combinations thereof. Furthermore, the traditional reductants may be combined with the oxygen-containing reductants to form a reducing gas. Oxygen-containing gases that are used in embodiments of the present invention are traditionally used in the chemical art as an oxidant. However, ligands on an organometallic compound containing a noble metal (e.g., Ru) are usually more susceptible to the oxygen-containing reductants than the noble metal. Therefore, the ligand is generally oxidized from the metal center while the metal ion is reduced to form the elemental metal. In one example, the reducing gas is air containing ambient oxygen as the reductant. The air may be dried over sieves to reduce ambient water.

Suitable tungsten-containing compounds include tungsten hexafluoride (WF₆), tungsten hexachloride (WCl₆), tungsten hexacarbonyl (W(CO)₆), bis(cyclopentadienyl)tungsten dichloride (Cp₂WCl₂) and mesitylene tungsten tricarbonyl (C₉H₁₂W(CO)₃), as well as derivatives thereof. Suitable reducing compounds include silane compounds, borane compounds and hydrogen. Silane compounds include silane, disilane, trisilane, tetrasilane, chlorosilane, dichlorosilane, tetrachlorosilane, hexachlorodisilane, methylsilanes and other alkylsilanes and derivatives thereof, while borane compounds include borane, diborane, triborane, tetraborane, pentaborane, triethylborane and other alkylboranes and derivatives thereof. Preferred reducing compounds and soak compounds include silane, disilane, diborane, hydrogen and combinations thereof.

In one example, a seed layer may be deposited on substrate 121 within process chamber 600 during a deposition process at step 1340. In one embodiment, substrate 121 may be exposed to a process gas containing a seed layer precursor, such as Cp₂Ru and a reagent, such as B₂H₆ during a CVD process. The precursors are generally provided from gas panel to interior volume of chamber body 651 through flow control ring. The precursors are generally provided from gas source 159 to inner chamber 101 through faceplate 152.

In one embodiment, the precursors may be introduced at step 140 into process chamber or exposed to substrate 121 by inlet channel 156 simultaneously, such as during a traditional CVD process or sequentially, such as during an ALD process. The ALD process may expose the substrate to at least two deposition gases, such that, the substrate is sequentially exposed to a first precursor such as Cp₂Ru and a second precursor, such as B₂H₆. Although one inlet channel 156 is shown, it is contemplated that the first precursor and the second precursor are provided to process chamber 600 in separate gas lines. The temperature may be controlled for each gas line.

A description of CVD and ALD processes and apparatuses that may be modified (e.g., incorporating a UV radiation source) and chemical precursors that may be useful for depositing conductive materials are further disclosed in commonly assigned U.S. Pat. App. Pub. No. 2006-0128150, published Jun. 15, 2006, entitled RUTHENIUM AS AN UNDERLAYER FOR TUNGSTEN FILM DEPOSITION, which is herein incorporated by reference in its entirety.

As the first precursor, for example, a ruthenium containing precursor, such as Cp₂Ru and a reducing agent, such as B₂H₆ are combined in the process chamber, ruthenium is formed on the substrate surface.

A carrier gas may be provided during step 1240 to control the partial pressure of the first precursor and the second precursor. The total internal pressure of a single wafer process chamber may be at a pressure within a range from about 100 mTorr to about 740 Torr, preferably, from about 250 mTorr to about 100 Torr, and more preferably, from about 500 mTorr to about 50 Torr. In one example, the internal pressure of the process chamber is maintained at a pressure of about 10 Torr or less, preferably, about 5 Torr or less, and more preferably, about 1 Torr or less. In some embodiments, the carrier gas may be provided to control the partial pressure of the first precursor or the second precursor within a range from about 100 mTorr to about 1 Torr for batch processing systems. Examples of suitable carrier gases include nitrogen, hydrogen, argon, helium, forming gas, or combinations thereof.

The substrate, the first precursor, and/or the second precursor may be exposed to an energy beam or a flux of energy generated by the photoexcitation system during the deposition process at step 1240. The use of the energy beam advantageously increases the deposition rate and improves surface diffusion or within a range from about 1 minute to about 10 minutes to facilitate post deposition treatment by photoexcitation.

In one example, volatile compounds or contaminants may be removed from the deposited film surface by exposing the substrate to an energy beam having a photon energy within a range from about 3.2 eV to about 4.5 eV is generated by lamp 790 is utilized to dissociate tungsten or titanium precursors and nitrogen precursors within process chamber 600. Thus, excimer lamps, such as XeBr* (283 nm/4.41 eV), Br₂* (289 nm/4.29 eV), XeCl* (308 nm/4.03 eV), I₂* (342 nm/3.63 eV), XeF* (351 nm/3.53 eV) may be selected to remove hydrogen from the seed layer. It is contemplated that the rotational speed of the substrate may be changed, for example, by increasing the rotation speed in step 1350 relative to the preceding deposition step.

In another embodiment, the substrate 121 may be removed from the process chamber 600 and the process chamber 600 is subsequently exposed to a chamber clean process during step 1360. The process chamber may be cleaned using a photoexcited cleaning agent. In one embodiment, the cleaning agent includes fluorine.

Process chamber 600 may be cleaned during a chamber clean process to enhance deposition performance. For example, the chamber clean process may be used to remove contaminants contained on the surfaces of process chamber 600 or contaminants contained on windows 793, thereby minimizing transmission losses of the energy beam or flux traveling through window 793 and maximizing the energy transferred to the gases and surfaces. Window 793 may be cleaned with greater frequency than process chamber 600, for example, process chamber 600 may be cleaned after processing a number of substrates while window 793 is cleaned after processing each substrate.

Seed layers deposited utilizing process 1300 as described herein may be used throughout electronic features/devices due to several physical properties. In one embodiment, seed layers may be deposited during process 1300 as layers on a substrate to form electronic features, such as an integrated circuit (FIG. 14).

In the case of ALD deposition, a UV anneal treatment with or without a reactant gas may be performed with the aforementioned processes. This UV-anneal treatment is generally performed in a temperature range between 30° C. and 1000° C., using UV energy between 123 nm and 500 nm. This anneal treatment may be performed during the purge cycles, after completion of each cycle, after intermittent cycles, after the completion of all cycles for required thickness, and after completion of the process run. When used with oxygen and ozone, this process enhances the oxygen content in the film, helps maintain layer-by layer stoichiometry of the high-K oxides, nitrides, and oxynitrides, eliminate carbon and other impurities, densities the film, and reduces leakage current.

FIG. 14A-14D illustrate schematic cross-sectional views of an integrated circuit fabrication sequence. FIG. 14A illustrates a cross-sectional view of substrate 1400 having a metal contact layer 1404 and dielectric layer 1402 formed thereon. Substrate 1400 may comprise a semiconductor material such as, for example, silicon, germanium, or gallium arsenide. Dielectric layer 1402 may comprise an insulating material such as, silicon dioxide, silicon nitride, SOI, silicon oxynitride and/or carbon-doped silicon oxides, such as SiOₓC_{y}, for example, BLACK DIAMOND™ low-k dielectric, available from Applied Materials, Inc., located in Santa Clara, Calif. Metal contact layer 1404 comprises a conductive material, for example, tungsten, copper, aluminum and alloys thereof. A via or aperture 1403 may be defined in the dielectric layer 1402 to provide openings over metal contact layer 1404. Aperture 1403 may be defined in dielectric layer 1402 using conventional lithography and etching techniques.

Barrier layer 1406 may be formed on dielectric layer 1402 as well as in aperture 1403. Barrier layer 1406 may include one or more barrier materials such as, for example, tantalum, tantalum nitride, tantalum silicon nitride, titanium, titanium nitride, titanium silicon nitride, tungsten nitride, silicon nitride, ruthenium nitride, derivatives thereof, alloys thereof and combinations thereof. Barrier layer 1406 may be formed using a suitable deposition process, such as ALD, CVD, PVD or electroless deposition. For example, tantalum nitride may be deposited using a CVD process or an ALD process wherein tantalum-containing compound or tantalum precursor (e.g., PDMAT) and nitrogen-containing compound or nitrogen precursor (e.g., ammonia) are reacted. In one embodiment, tantalum and/or tantalum nitride is deposited as barrier layer 1406 by an ALD process as described in commonly assigned U.S. patent Ser. No. 10/281,079, filed Oct. 25, 2002, and is herein incorporated by reference. In one example, a Ta/TaN bilayer may be deposited as barrier layer 1406, wherein the tantalum layer and the tantalum nitride layer are independently deposited by ALD, CVD and/or PVD processes.

A layer 1408, for example, a ruthenium layer may be deposited on barrier layer 1406 by ALD, CVD or PVD processes, preferably, by an ALD process. A nucleation layer 1410, for example a tungsten nucleation layer, may be formed on the layer 1408, as depicted in FIG. 14C. The nucleation layer 1410 is deposited by using conventional deposition techniques, such as ALD, CVD or PVD. Preferably, nucleation layer 1410 is deposited by an ALD process, such as alternately adsorbing a tungsten-containing precursor and a reducing compound. A bulk layer 1412, for example, a tungsten bulk layer may be formed on top of the nucleation layer 1410.

While the foregoing is directed to embodiments of the invention, other and further embodiments of the invention may be devised without departing from the basic scope thereof, and the scope thereof is determined by the claims that follow.

What is claimed is:

1. A method for forming a metal nitride on a substrate, the method comprising:
positioning a substrate within a process chamber;
exposing the substrate to a deposition gas comprising a metal containing precursor and a nitrogen containing precursor;
exposing the deposition gas to an energy beam derived from a UV-source within the process chamber; and
depositing a metal nitride on the substrate.

2. The method of claim 1, wherein the substrate is exposed to the energy beam during a pretreatment process prior to depositing the metal nitride or the substrate is exposed to the energy beam during a post-treatment process after depositing the metal nitride.

3. The method of claim 2, wherein native oxides are removed from the substrate during the pretreatment process.

4. The method of claim 2, wherein the energy beam has a photon energy within a range from about 2 eV to about 10 eV.

5. The method of claim 4, wherein the photon energy is within a range from about 3.2 eV to about 4.5 eV.

6. The method of claim 4, wherein an energy delivery gas passes through the energy beam during the pretreatment process or the post-treatment process and the energy delivery gas comprises a gas selected from the group consisting of neon, argon, krypton, xenon, argon bromide, argon chloride, krypton bromide, krypton chloride, krypton fluoride, xenon fluorides, xenon chlorides, xenon bromides, fluorine, chlorine, bromine, excimers thereof, radicals thereof, derivatives thereof, and combinations thereof.

7. The method of claim 6, wherein the energy delivery gas further comprises nitrogen gas or hydrogen gas.

8. The method of claim 2, wherein the metal containing precursor is selected from a group consisting of tungsten hexafluoride (WF₆), tungsten carbonyl (W(CO)₆), tantalum pentachloride (TaCl₅), pentakis(diethylamido) tantalum (PDEAT) (Ta(Net₂)₅), pentakis (ethylmethylamido) tantalum (PEMAT) (Ta(N(Et)(Me))₅), pentakis(dimethylamido) tantalum (PDMAT) (Ta(Nme₂)₅), titanium tetrachloride (TiCl₄), tetrakis(diethylamido) titanium (TDEAT) (Ti(Net₂)₄), tetrakis(ethylmethylamido) titanium (TEMAT) (Ti(N(Et)(Me))₄), and tetrakis(dimethylamido) titanium (TDMAT) (Ti(NMe₂)₄), derivatives thereof, or combinations thereof.

9. The method of claim 8, wherein the nitrogen precursor is selected from the group consisting of atomic nitrogen, nitrogen, azide, ammonia, hydrazine, amine compounds, hydrazine compounds, azide compounds, radicals thereof, derivatives thereof, and combinations thereof.

10. A method for forming a metal oxide on a substrate, the method comprising:
positioning a substrate within a process chamber;
exposing the substrate to a deposition gas comprising a metal containing precursor and an oxygen containing precursor;
exposing the deposition gas to an energy beam derived from a UV-source within the process chamber; and
depositing a metal oxide on the substrate.

11. The method of claim 10, wherein the substrate is exposed to the energy beam during a pretreatment process prior to depositing the metal oxide.

12. The method of claim 11, wherein native oxides are removed from the substrate during the pretreatment process.

13. The method of claim 11, wherein the energy beam has a photon energy within a range from about 2 eV to about 10 eV.

14. The method of claim 13, wherein the photon energy is within a range from about 3.2 eV to about 4.5 eV.

15. The method of claim 13, wherein an energy delivery gas passes through the energy beam during the pretreatment process or the post-treatment process and the energy delivery gas comprises a gas selected from the group consisting of neon, argon, krypton, xenon, argon bromide, argon chloride, krypton bromide, krypton chloride, krypton fluoride, xenon fluorides, xenon chlorides, xenon bromides, fluorine, chlorine, bromine, excimers thereof, radicals thereof, derivatives thereof, and combinations thereof.

16. The method of claim 15, wherein the energy delivery gas further comprises nitrogen gas or hydrogen gas.

17. The method of claim 10, wherein the oxygen precursor is selected from the group consisting of atomic oxygen, oxygen, ozone, water, hydrogen peroxide, radicals thereof, derivatives thereof, and combinations thereof.

18. The method of claim 10, wherein the metal containing precursor is selected from the group consisting of (Et₂N)₄Hf, (Me₂N)₄Hf, (MeEtN)₄Hf, (^{t}BuC₅H₄)₂HfCl₂, (C₅H₅)₂HfCl₂, (EtC₅H₄)₂HfCl₂, (Me₅C₅)₂HfCl₂, (Me₅C₅)HfCl₃, (ⁱPrC₅H₄)₂HfCl₂, (ⁱPrC₅H₄)HfCl₃, (^{t}BuC₅H₄)₂HfMe₂, (acac)₄Hf, (hfac)₄Hf, (tfac)₄Hf, (thd)₄Hf, (NO₃)₄Hf, (^{t}BuO)₄Hf, (ⁱPrO)₄Hf, (EtO)₄Hf, (MeO)₄Hf or derivatives thereof.

19. The method of claim 10, wherein the metal containing precursor is selected from the group consisting of ZrCl₄, Cp₂Zr, (Me₂N)₄Zr, (Et₂N)₄Zr, TaF₅, TaCl₅, (^{t}BuO)₅Ta, (Me₂N)₅Ta, (Et₂N)₅Ta, (Me₂N)₃Ta(N^{t}Bu), (Et₂N)₃Ta(N^{t}Bu), TiCl₄, TiI₄, (ⁱPrO)₄Ti, (Me₂N)₄Ti, (Et₂N)₄Ti, AlCl₃, Me₃Al, Me₂AlH, (AMD)₃La, ((Me₃Si)(^{t}Bu)N)₃La, ((Me₃Si)₂N)₃La, (^{t}Bu₂N)₃La, (ⁱPr₂N)₃La, derivatives thereof or combinations thereof.

20. The method of claim 10, wherein the substrate is exposed to the energy beam during a post-treatment process after depositing the metal oxide.

21. The method of claim 20, wherein the energy beam has a photon energy within a range from about 2 eV to about 10 eV.

22. The method of claim 21, wherein the photon energy is within a range from about 3.2 eV to about 4.5 eV.

23. A method for forming a metal layer on a substrate, the method comprising:
positioning a substrate within a process chamber;
exposing the substrate to a deposition gas comprising a metal containing precursor and a reducing gas;
exposing the deposition gas to an energy beam derived from a UV-source within the process chamber; and
depositing a metal layer on the substrate.

24. The method of claim 23, wherein the energy beam has a photon energy within a range from about 2 eV to about 10 eV.

25. The method of claim 24, wherein the photon energy is within a range from about 3.2 eV to about 4.5 eV.

26. The method of claim 24, wherein an energy delivery gas passes through the energy beam during the pretreatment process or the post-treatment process and the energy delivery gas comprises a gas selected from the group consisting of neon, argon, krypton, xenon, argon bromide, argon chloride, krypton bromide, krypton chloride, krypton fluoride, xenon fluorides, xenon chlorides, xenon bromides, fluorine, chlorine, bromine, excimers thereof, radicals thereof, derivatives thereof, and combinations thereof.

27. The method of claim 26, wherein the energy delivery gas further comprises nitrogen gas or hydrogen gas.

28. The method of claim 23, wherein the metal containing precursor is selected from a group consisting of bis(cyclopentadienyl)ruthenium (Cp₂Ru), bis(methylcyclopentadienyl)ruthenium, bis(ethylcyclopentadienyl)ruthenium, bis(pentamethylcyclopentadienyl)ruthenium, bis(2,4-dimethylpentadienyl)ruthenium, bis(2,4-diethylpentadienyl)ruthenium, bis(2,4-diisopropylpentadienyl)ruthenium, bis(2,4-ditertbutylpentadienyl)ruthenium, bis(methylpentadienyl)ruthenium, bis(ethylpentadienyl)ruthenium, bis(isopropylpentadienyl)ruthenium, bis(tertbutylpentadienyl)ruthenium, derivatives thereof and combinations thereof. In some embodiments, other ruthenium-containing compounds include tris(2,2,6,6-tetramethyl-3,5-heptanedionato)ruthenium, dicarbonyl pentadienyl ruthenium, ruthenium acetyl acetonate, (2,4-dimethylpentadienyl)ruthenium(cyclopentadienyl), bis(2,2,6,6-tetramethyl-3,5-heptanedionato)ruthenium(1,5-cyclooctadiene), (2,4-dimethylpentadienyl)ruthenium(methylcyclopentadienyl), (1,5-cyclooctadiene)ruthenium(cyclopentadienyl), (1,5-cyclooctadiene)ruthenium(methylcyclopentadienyl), (1,5-cyclooctadiene)ruthenium(ethylcyclopentadienyl), (2,4-dimethylpentadienyl)ruthenium(ethylcyclopentadienyl), (2,4-dimethylpentadienyl)ruthenium(isopropylcyclopentadienyl), bis(N,N-dimethyl 1,3-tetramethyl diiminato)ruthenium(1,5-cyclooctadiene), bis(N,N-dimethyl 1,3-dimethyl diiminato)ruthenium(1,5-cyclooctadiene), bis(allyl)ruthenium(1,5-cyclooctadiene), (η⁶-C₆H₆)ruthenium(1,3-cyclohexadiene), bis(1,1-dimethyl-2-aminoethoxylato)ruthenium(1,5-cyclooctadiene), bis(1,1-dimethyl-2-aminoethylaminato)ruthenium(1,5-cyclooctadiene), derivatives thereof and combinations thereof.

29. The method of claim 23, wherein the metal containing precursor is selected from a group consisting of bis(allyl)palladium, bis(2-methylallyl)palladium, (cyclopentadienyl)(allyl)palladium, dimethyl(cyclooctadiene)platinum, trimethyl(cyclopentadienyl)platinum, trimethyl(methylcyclopentadienyl)platinum, cyclopentadienyl(allyl)platinum, methyl(carbonyl)cyclopentadienylplatinum, trimethyl(acetylacetonato)platinum, bis(acetylacetonato)platinum, bis(cyclopentadienyl)cobalt, (cyclopentadienyl)(cyclohexadienyl)cobalt, cyclopentadienyl(1,3-hexadienyl)cobalt, (cyclobutadienyl)(cyclopentadienyl)cobalt, bis(methylcyclopentadienyl)cobalt, (cyclopentadienyl)(5-methylcyclopentadienyl)cobalt, bis(ethylene) (pentamethylcyclopentadienyl)cobalt, bis(methylcyclopentadienyl)nickel, bis(carbonyl)(cyclopentadienyl)rhodium, bis(carbonyl)(ethylcyclopentadienyl)rhodium, bis(carbonyl)(methylcyclopentadienyl)rhodium, bis(propylene)rhodium, derivatives thereof and combinations thereof.

30. The method of claim 23, wherein the reducing gas is selected from a group consisting of hydrogen, ammonia (NH₃), borane (BH₃), diborane (B₂H₆), triborane, tetraborane, pentaborane, alkylboranes, such as triethylborane (Et₃B), oxygen, nitrous oxide (N₂O), nitric oxide (NO), nitrogen dioxide (NO₂)derivatives thereof and combinations thereof.

31. The method of claim 23, wherein the substrate is exposed to the energy beam during a pretreatment process prior to depositing the metal oxide.

32. The method of claim 31, wherein native oxides are removed from the substrate during the pretreatment process.

33. The method of claim 31, wherein the energy beam has a photon energy within a range from about 2 eV to about 10 eV.

34. The method of claim 33, wherein the photon energy is within a range from about 3.2 eV to about 4.5 eV.

35. The method of claim 23, wherein the substrate is exposed to the energy beam during a post-treatment process after depositing the metal oxide.

36. The method of claim 35, wherein the energy beam has a photon energy within a range from about 2 eV to about 10 eV.

37. The method of claim 36, wherein the photon energy is within a range from about 3.2 eV to about 4.5 eV.
